(19) United States
(12) Patent Application Publication
(10) Pub. No.: US 2025/0081579 A1
(43) Pub. Date: Mar. 6, 2025

(54) METALLIZATIONS FOR SEMICONDUCTOR POWER DEVICES

(71) Applicant: Wolfspeed, Inc., Durham, NC (US)

(72) Inventors: Jonathan Van Buskirk, Royse City, TX (US); Brice McPherson, Springdale, AZ (US); Paul Rheinheimer, Tucson, AZ (US); Daniel Flint, Cary, NC (US); Joshua Johnen, Raleigh, NC (US)

(21) Appl. No.: 18/950,476

(22) Filed: Nov. 18, 2024

Related U.S. Application Data
(63) Continuation-in-part of application No. 18/612,302, filed on Mar. 21, 2024.

(51) Int. Cl. H01L 29/417; H01L 23/00; H01L 29/78

(52) U.S. Cl. CPC H10D 64/252; H01L 24/37; H01L 24/45; H01L 24/46; H01L 24/73; H10D 30/63; H01L 2224/37005; H01L 2224/45014; H01L 2224/45015; H01L 2224/46; H01L 2224/73101; H01L 2924/3511; H01L 2924/37001

(57) ABSTRACT

A method includes providing a plurality of semiconductor devices on a semiconductor structure, providing a top side metallization on a first side of the semiconductor structure, wherein the top side metallization comprises a plurality of bond pads on each of the semiconductor devices, and providing a back side metallization on a second side of the semiconductor structure opposite the first side of the semiconductor structure. The back side metallization is not provided on portions of the second side of the semiconductor structure corresponding to dicing streets between the semiconductor devices.

### CROSS REFERENCE TO RELATED APPLICATION

This application is a continuation-in-part of U.S. patent application Ser. No. 18/612,302, entitled “POWER DEVICES WITH MULTIPLE METAL LAYER THICKNESSES” (Attorney Docket 5308-3412US1), filed on Mar. 21, 2024, and assigned to the same assignee as the present application and is incorporated herein by reference as if set forth in its entirety.

### FIELD

The present disclosure relates to semiconductor power devices, and in particular to metallizations for power semiconductor devices.

### BACKGROUND

Power semiconductor devices typically have relatively thin top side (or top side) and back side metallizations. This is the result of a number of factors, including metal deposition process capabilities, process time and cost, and stress induced warpage of the wafer. For high current power devices, however, these thin metallization layers introduce limitations to performance and reliability of the product. This is particularly so for wide band gap devices which offer considerably higher potential current densities. These higher densities require advancements in the devices and their associated packages to achieve their full potential.

The presence of thin layers may limit performance and reliability at both the device and package levels. For example, at the device level, thin metal layers may result in high current concentrations, uneven current distribution, localized heating and/or localized thermal stresses. At the package level, thin metal layers may result in limitations in the power interconnection size (wire diameter, ribbon thickness, etc.), limitations in the power interconnection material (softer materials vs. harder materials), a higher risk of device damage during wire/ribbon bonding, localized thermal stresses at the interconnection interface and/or limiting the allowable current (i.e. the device is not fully utilized).

Thicker metallization, particularly on the top side metal layer, may help address these issues on multiple fronts. For example, the use of thicker metallization (particularly top side metallization) may allow buffering the current to a more even distribution, and/or may reduce the localized heating and spreading it away from critical interfaces. Additionally, the use of thicker metallization may help to improve robustness for larger size power interconnections and/or may provide a capability to apply compatible materials for different power interconnection materials.

Creating the thicker metallization on a semiconductor wafer, however, has challenges which limit to what is practical and possible. Wafers are relatively thin at the time of processing, and may encounter multiple high temperature conditions as the devices are formed. Thicker metal layers, particularly if only on one side, can introduce warpage and distortion that are often too high for usage.

### SUMMARY

A method according to some embodiments includes providing a plurality of semiconductor devices on a semiconductor structure, providing a top side metallization on a first side of the semiconductor structure, wherein the top side metallization comprises a plurality of bond pads on each of the semiconductor devices, and providing a back side metallization on a second side of the semiconductor structure opposite the first side of the semiconductor structure, wherein the back side metallization is not provided on portions of the second side of the semiconductor structure corresponding to dicing streets between the semiconductor devices.

The method may further include singulating the semiconductor structure along the dicing streets.

In some embodiments, singulating the semiconductor structure may include sawing the semiconductor structure along the dicing streets.

In some embodiments, providing the back side metallization may include providing a blanket metallization on the second side of the semiconductor structure and selectively removing metal from portions of the second side of the semiconductor structure corresponding to dicing streets.

In some embodiments, selectively removing metal may include selectively ablating the back side metallization with a laser.

Providing the back side metallization may include selectively depositing metal on the second side of the semiconductor structure other than in portions of the second side of the semiconductor structure corresponding to dicing streets.

In some embodiments, providing the back side metallization may include forming contact pads on back sides of the semiconductor devices, wherein corners of the contact pads are shaped to reduce stress at corners of the contact pads caused by mounting the semiconductor devices.

The corners of the contact pads may be rounded. In some embodiments, corners of one of the contact pads are rounded with a radius that is less than about one half of the length of a shortest side of the one of the contact pads.

In some embodiments, the corners of the one of the contact pads are rounded with a radius that is from about 10% to 50% of the length of the shortest side of the one of the contact pads, and in some embodiments from about 40% to 50% of the length of the shortest side of the one of the contact pads.

In some embodiments, the corners of the contact pads are chamfered, and in some embodiments the corners of the contact pads have polygonal shapes. After shaping of the corners of the contact pads, the contact pads may have no peripheral angles less than 120 degrees.

Shaping the corners of the contact pads is performed by selectively depositing a plurality of metal layers.

The back side metallization may not be provided on edges of the semiconductor devices.

The method may further include selectively removing the back side metallization from portions of the second side of the semiconductor structure other than the portions of the second side of the semiconductor structure corresponding to the dicing streets between the semiconductor devices.

Providing the back side metallization may include depositing a plurality of metal layers on the second side of the semiconductor structure.

Providing the back side metallization may include performing patterned deposition of metal on the second side of the semiconductor structure.

In some embodiments, providing the back side metallization may include performing depositing metal on the second side of the semiconductor structure and selectively etching portions of the deposited metal.

A method according to some embodiments includes providing a plurality of semiconductor devices on a semiconductor structure, providing a top side metallization on a first side of the semiconductor structure, wherein the top side metallization comprises a plurality of bond pads on each of the semiconductor devices, and providing a back side metallization on a second side of the semiconductor structure opposite the first side of the semiconductor structure, wherein portions of the second side of the semiconductor structure are free of the back side metallization.

The method may further include selectively removing the back side metallization from portions of the second side of the semiconductor structure.

Providing the back side metallization may include depositing metal on the second side of the semiconductor structure other than the portions of the second side of the semiconductor structure that are free of the back side metallization.

The portions of the second side of the semiconductor structure that are free of the back side metallization may include edges of the semiconductor structure.

Selectively removing the back side metallization from portions of the second side of the semiconductor structure may include selectively removing the back side metallization from portions of the second side of the semiconductor structure corresponding to dicing streets between the semiconductor devices.

In some embodiments, selectively removing the back side metallization from portions of the second side of the semiconductor structure may include selectively removing the back side metallization from portions of the second side of the semiconductor structure near corners of the semiconductor devices.

In some embodiments, selectively removing the back side metallization from portions of the second side of the semiconductor structure may include selectively removing the back side metallization from portions of the second side of the semiconductor structure to form circular features in the back side metallization near corners of the semiconductor devices.

The method may further include forming a protective overlay on the top side metallization, wherein the protective overlay may include an opening aligned with at least one of the bond pads, wherein the opening has rounded corners.

The protective overlay may include polyimide.

A semiconductor device according to some embodiments includes a semiconductor structure, a top side metallization on a first side of the semiconductor structure, wherein the top side metallization comprises a plurality of bond pads, and a back side metallization on a second side of the semiconductor structure opposite the first side of the semiconductor structure. Edges of the back side metallization are inset from edges of the semiconductor structure.

The back side metallization may include rounded, chamfered or polygonal corners.

The back side metallization may include a first metal layer and a second metal layer on the first metal layer, wherein edges of the first metal layer are inset from edges of the semiconductor structure and edges of the second metal layer are inset from the edges of the first metal layer.

The semiconductor device may further include a protective overlay on the top side metallization, wherein the protective overlay may include an opening aligned with at least one of the bond pads, wherein the opening has rounded corners.

The back side metallization may include raised regions near corners of the back side metallization.

The raised regions comprise linear and/or circular regions of metal.

The back side metallization may include regions of removed material near corners of the back side metallization. The regions of removed regions material comprise linear and/or circular regions where metal has been removed from the back side metallization.

A method according to some embodiments includes providing a plurality of semiconductor devices on a semiconductor structure, providing a top side metallization on a first side of the semiconductor structure, wherein the top side metallization comprises a plurality of bond pads on each of the semiconductor devices, and forming a protective overlay on the top side metallization, wherein the protective overlay comprises an opening aligned with at least one of the bond pads, wherein the opening has rounded corners.

The method may further include providing a back side metallization on a second side of the semiconductor structure opposite the first side of the semiconductor structure, wherein portions of the second side of the semiconductor structure are free of the back side metallization.

The opening in the protective overlayer may be formed by two edges of the opening in the protective overlayer, and the corners of the overlayer may be rounded with a radius that is less than about one half of the length of a shorter of the two edges of the opening.

In some embodiments, the corners of the overlayer are rounded with a radius that is from about 10% to 50% of the length of the shorter of the two edges, and in some embodiments the corners of the overlayer are rounded with a radius that is from about 40% to 50% of the length of the shorter of the two edges.

### BRIEF DESCRIPTION OF THE DRAWINGS

FIG. 1 illustrates an example of a MOSFET device.

FIG. 2 illustrates an example of a MOSFET circuit.

FIGS. 3, 4 and 5 illustrate a cross-sectional views of MOSFET devices including a plurality of MOSFET cells.

FIG. 6 illustrates semiconductor wafers experiencing various forms of warpage.

FIG. 7 illustrates a semiconductor device according to some embodiments.

FIGS. 8A and 8B, 9 and 10 illustrate metal stacks on a semiconductor device according to some embodiments.

FIGS. 11, 12, 13, 14, 15, 16, 17, 18, 19 and 20 depict example top side patterns for wire bonding in devices including a plurality of bond pads according to various embodiments.

FIGS. 21, 22, 23, 24 and 25 illustrate back side metallization patterns according to various embodiments.

FIG. 26 illustrates back side metallization structures according to various embodiments.

FIGS. 27, 28 and 29 illustrate embodiments in which the top side metallization includes diagonalized bond pad arrangements.

FIGS. 30 and 31 illustrate conventional back side metal formation and singulation.

FIGS. 32 and 33 illustrate back side metal formation and singulation according to some embodiments.

FIGS. 34 and 35 illustrate techniques for back side metal formation according to various embodiments.

FIGS. 36A and 36B illustrate a semiconductor device mounted on a device substrate.

FIG. 37 illustrates conventional top side contact formation.

FIGS. 38 and 39 illustrate top side contact formation according to various embodiments.

FIGS. 40 and 41 illustrate formation of corners of a contact pad.

FIGS. 42, 43 and 44 illustrate formation of metal features near corners of a contact pad.

### DETAILED DESCRIPTION OF EMBODIMENTS

Wide Band Gap power devices, including devices based on silicon carbide (SiC), gallium nitride (GaN), and the like offer a high level of performance benefits, including high voltage blocking, low on-resistance, high current, fast switching, low switching losses, high junction temperatures, and high thermal conductivity. Ultimately, these characteristics result in a notable increase in potential power density, which is power processed per area or volume.

Achieving this potential, however, requires addressing significant challenges at the package and system level. The higher voltages, currents, and switching speeds manifest into significantly higher physical stresses applied onto smaller and more constrained areas. To fully take advantage of what SiC technology has to offer, several challenges must be addressed both at the device and the package level, including the formation of electrical interconnections from the device top sides to the package substrate or terminals. Other challenges include waste heat removal, including conduction and switching losses from the devices, and effective electrical isolation between high voltage potentials. Wide bandgap power devices should also have the capability to handle high steady state currents, capability to handle high transient current events, mechanical robustness to reliably operate in high stress, high temperature, high vibration environments. Such devices should be compatible with advanced interconnection materials, structures, and techniques, as well as with advanced device attach materials, structures, and techniques.

Power packages contain power semiconductor devices, including metal-oxide semiconductor field effect transistors (MOSFETs), junction field effect transistors (JFETs), insulated gate bipolar transistors (IGBTs), diodes, and the like, arranged into a variety of circuit topologies. A device package serves many functions, including electrical interconnection, electrical isolation, heat transfer, and mechanical structure. The package protects devices from environmental contamination and moisture, and provides external electrical and thermal connection interfaces. The package should also provide compliance with safety standards, such as voltage creepage and clearance distances.

Generally speaking, power packages can be categorized as either a discrete package, housing a single device, or a power module, housing multiple devices. Power modules may place multiple devices in parallel and arrange them into various circuit topologies. As an example, a single switch position package that houses one device would be categorized a discrete, and one that houses multiple devices in parallel (to increase output current) would be considered a power module.

Packages conventionally use, but are not limited to, some combination of the following components, each providing multiple functions. These are summarized in the following table. The terms used in this disclosure, unless otherwise indicated, follow the definitions outlined in Table 1 below.

TABLE 1
Definitions

| Item | Description |
|---|---|
| Power Device(s) | Controllable switches MOSFET, IGBT, and the like and Diodes |
| Substrate, Power | Layered metal and ceramic for high current electrical interconnection, |
| | high voltage isolation, high thermal conductivity, coefficient of thermal |
| | expansion (CTE) matching, and external thermal interface |
| Substrate, Signal | Layered Printed Circuit Board (PCB), layered metal and ceramic, thick |
| | film, and the like for high frequency electrical interconnection and high |
| | voltage isolation |
| Terminal, Power | Metal contact for high current external connection and internal |
| | interconnection |
| Terminal, Signal | Metal contact or connector for high frequency external connection and |
| | internal interconnection |
| Lead Frame | Metal contact strip for high current external connection and internal |
| | interconnection; Contacts are joined together on a single sheet, often |
| | with multiple products per sheet, and are processed as an array and then |
| | formed and singulated |
| Base Plate | Metal or composite material for mechanical structure, high thermal |
| | conductivity, coefficient of thermal expansion (CTE) matching, and |
| | external thermal interface |
| Device Attach | Solder, adhesive, or sintered metal, and the like for mechanical structure, |
| | high current interconnection, and high thermal conductivity |
| Terminal Attach | Solder, adhesive, sintered metal, laser weld, ultrasonic weld, and the like |
| | for mechanical structure, high current interconnection, and high thermal |
| | conductivity |
| Substrate Attach | Solder, adhesive, or sintered metal, and the like for mechanical structure |
| | and high thermal conductivity |
| Interconnection | Conductive element forming an electrical connection between one |
| | electrical node and another |
| Wire Bonds, Power | Ultrasonically or thermosonically bonded large diameter wire, ribbon, |
| | and the like for high current electrical interconnection |
| Wire Bonds, Signal | Ultrasonically or thermosonically bonded small diameter wire, ribbon, |
| | and the like for low current electrical interconnection |
| Case / Housing | Injection molded case and lid, providing mechanical structure, high |
| | voltage isolation, and acting as a well for the encapsulation material |
| Mold Compound | Transfer or compression molded epoxy molding compound (EMC) for |
| | mechanical structure, high voltage isolation, coefficient of thermal |
| | expansion (CTE) matching, and low humidity absorption |
| Encapsulation | Soft, flexible silicone or similar encapsulation material for high voltage |
| | isolation, and low humidity absorption |
| Temperature Sensor | Passive or active element that can be used to monitor internal |
| | temperatures |
| Signal Circuitry | Resistors, capacitors, surface mount components, sensors, and the like |
| | for stabilization of the dynamic switching performance of the devices or |
| | for other internal circuit requirements, such as active miller clamping, |
| | etc. |

Some typical design requirements for power device packages include high power density (small package size), high current, high voltage, high temperature operation, low thermal resistance, low stray inductance, fast and clean switching, high efficiency through low on-resistance, high efficiency through high speed switching, thoughtful external terminal layout for effective interconnection, compliance with creepage and clearance standards, moisture sensitivity level (MSL) compliance, and low cost.

A power semiconductor device is typically vertical, meaning power flows from top the back side to the top side of the chip (or vice versa). While there are many types of power devices where this technique applies, a MOSFET will be used for the purposes of explanation and illustration.

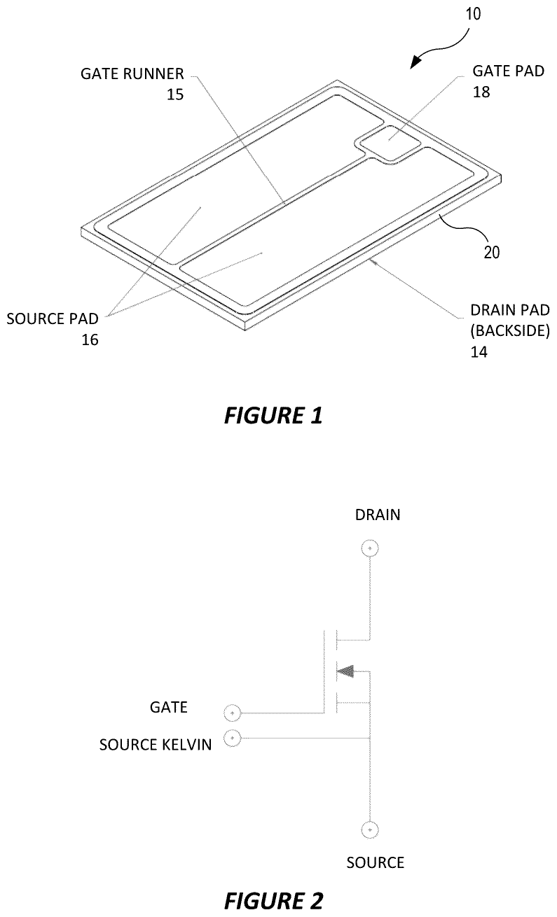

A power MOSFET is a three terminal device: (1) gate, (2) source, and (3) drain. Often an additional kelvin connection to the source terminal is made to optimize switching performance to isolate the power and signal loops. The gate and source are located on what will be referred to as the device top side, while the drain is located on the device back side. The high current path flows from the drain to source or source to drain, through the area of the device. An example MOSFET device is depicted in FIG. 1, and an example MOSFET circuit element is depicted in FIG. 2.

Referring to FIGS. 1 and 2, a MOSFET device 10 generally includes source, gate and drain terminals. The source terminal is connected to a pair of source pads 16 on the front or top side of a semiconductor die 20, and the gate terminal is connected to a gate pad 18 on the front or top side of the die 20. A gate runner 15 extends from the gate pad 18 and distributes the gate signal across the die 20. The drain terminal is connected to a drain pad 14 on the back side of the die 20.

The top side and back side metallizations that form the source pads 16, the gate pad 18 and the drain pad 14 generally include stack of metals to provide a variety of functions, such as ohmic contact, diffusion barrier, seed layers for plating or adhesion, and a capping bonding layer. The top side bonding layer is generally the thickest and is designed to be metallurgically compatible with the desired top side interconnection method. For example, the top side bonding layer may be aluminum to be most compatible with aluminum wire bonding or copper to be compatible with copper wire bonding. The back side metallization is also a stack of metals serving similar functions. Back side attaches tend to be a soldered, brazed, or sintered, rather than connected to wire bonds. The thickness of each layer is generally selected based on what is practical and cost effective to fabricate, what operating conditions are expected, and what performance requirements must be met.

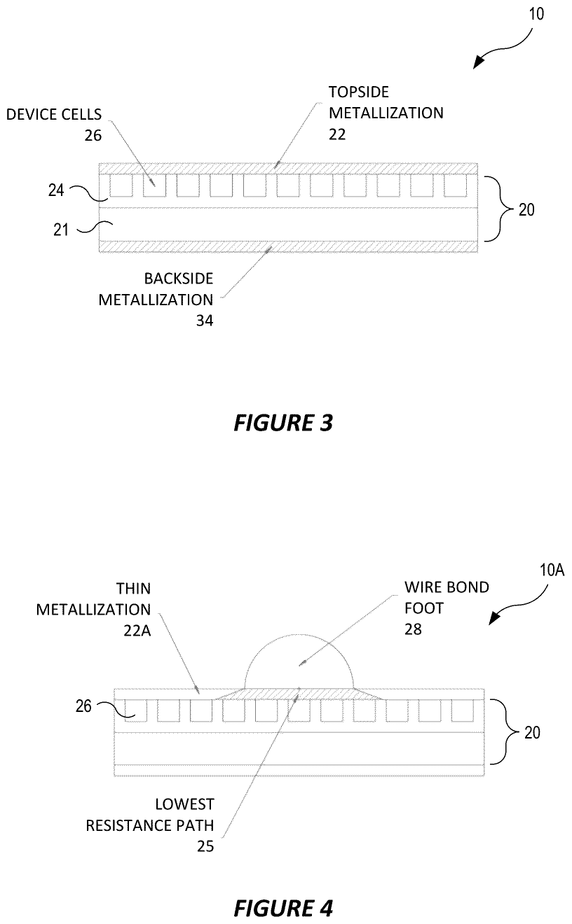

While a power semiconductor device operates as a single device, the physical chip layout is a large array of paralleled device ‘cells’ interconnected through the top side metallization and other functional layers. This is illustrated in FIG. 3 showing a sectional view of a power semiconductor device 10 including a substrate 21 and an epitaxial layer 24 in which a plurality of device cells 26 are formed. The power semiconductor device 10 may be a MOSFET, JFET, IGBT, diode, or other type of power semiconductor device. A back side metallization 34 is formed on the back, or bottom side of the die 20, and a top side metallization 22 is formed on the front, or top side of the die 20.

Note that there are many more features and functional layers than depicted in FIG. 3 for simplicity, and the layers are not to scale to show detail. The device cells 26 are paralleled through the top side metallization 22 providing contact to a source in the case of a MOSFET or JFET, an emitter in the case of an IGBT or an anode in the case of a power diode. The bulk of the semiconductor material is used for voltage isolation, with the back side metallization 34 providing electrical contact to the drain (for a MOSFET or JFET), collector (for an IGBT) or cathode (for a diode). Current flows vertically through the device from the part of the top side metallization 22 to the back side metallization 34.

In many cases, only a portion of the source pad 16 can be used for interconnection through wire bonds or ribbons. Hence, current must spread from these sites out towards the device cells 26. To effectively obtain the most performance out of the device 10, each of these device cells 26 should be fully utilized by carrying as much current as possible. Accordingly, distributing the current from the interconnection sites to each and every cell 26 is important for full device utilization. Distributing current equally among the cells also helps to spread heat evenly across the device.

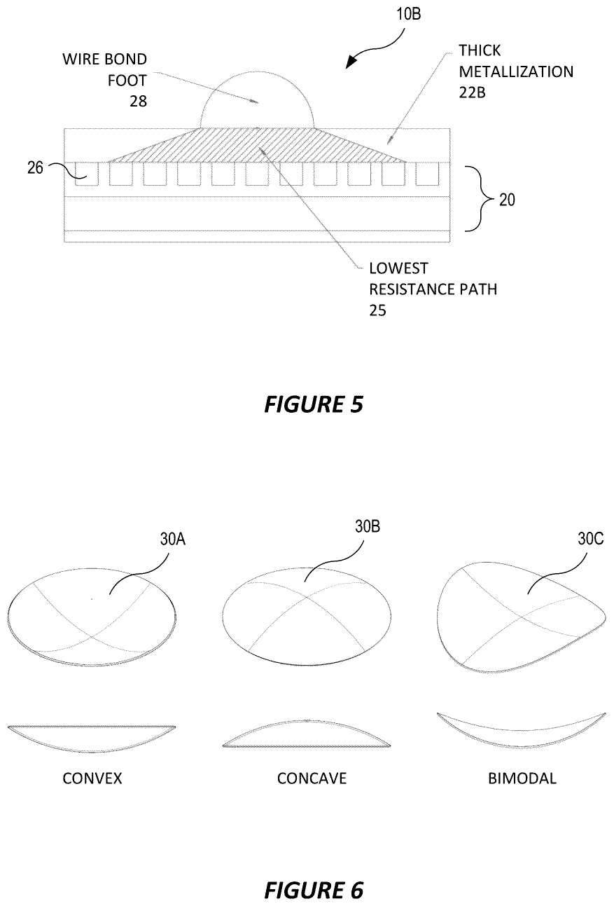

Using thicker metal may reduce the sheet resistance of the top side metallization 22, and may provide more cross sectional area through which current can readily spread. Increasing the thickness of the top side metallization layer 22 may allow for more cells to access a low resistance, efficient path to the input and output sites for current flow. This buffering effect may reduce high current concentrations and/or may reduce localized heating at the bonding interfaces. FIGS. 4 and 5 depict the buffering effect for thin (FIG. 4) top side metallizations 22A and thick (FIG. 5) top side metallizations 22B. Note that the device structure and scale of the image are used for description purposes and are not true to structure or scale for an actual device and package. A wire bond foot 28 is provided on the top side metallizations 22A, 22B, and current from the wire bond foot 28 flows into the die 20 via a lowest resistance path 25.

With a thin metallization 22A, there is limited room to laterally spread current and the resulting heat at the interface. These localized high current and heat densities can act to stress and weaken the interface. A thicker metallization 22B helps to buffer the current and heat to better distribute the energy away from the interfaces and evenly towards the device cells 26.

The application of a thicker top side metal may also improve device robustness for more aggressive interconnection methods. For example, copper wire is substantially harder than aluminum, and could cause damage to the sensitive device during the wire bonding process. Thicker metals can buffer out the energy applied to form the metallurgical bonds, and a ‘cushioning’ effect adding resilience and wider process windows. Thus, it may be preferable for the thicker top side metal 22A, 22B to improve the performance and bondability of copper wires. Moreover, due to the high conductivity of copper, the use of copper in the top side metal 22A, 22B can enable the use of fewer wire bonds, or may allow higher currents for a given number of wire bonds. The use of thick top side metal may also accommodate larger wire bond footprints, which can allow for more current.

While there are numerous benefits to thicker metallization layers, there are also many processing challenges. For example, there is a large coefficient of thermal expansion (CTE) imbalance between the semiconductor wafer and the metal layers. As the wafer experiences exposures to high temperatures during processing, the metal and semiconductor expand and contract at different rates, creating thermal stress. These thermal stresses can manifest as warpage of the wafer once cooled.

Warpage is a major problem which may reduce yield or render the wafer useless for further processing. Various types of warpage of wafers 30 are illustrated in FIG. 6. Depending on the temperature delta, metal layout, wafer thickness and diameter, and other factors, a warped wafer could be convex (30A), concave (30B), or bimodal (30C), as shown in FIG. 6. The risk of warpage exceeding a usable level increases as the metal thickness increases. This is particularly so if it is only increased on one side of the device.

### Selective Top Side Metallization

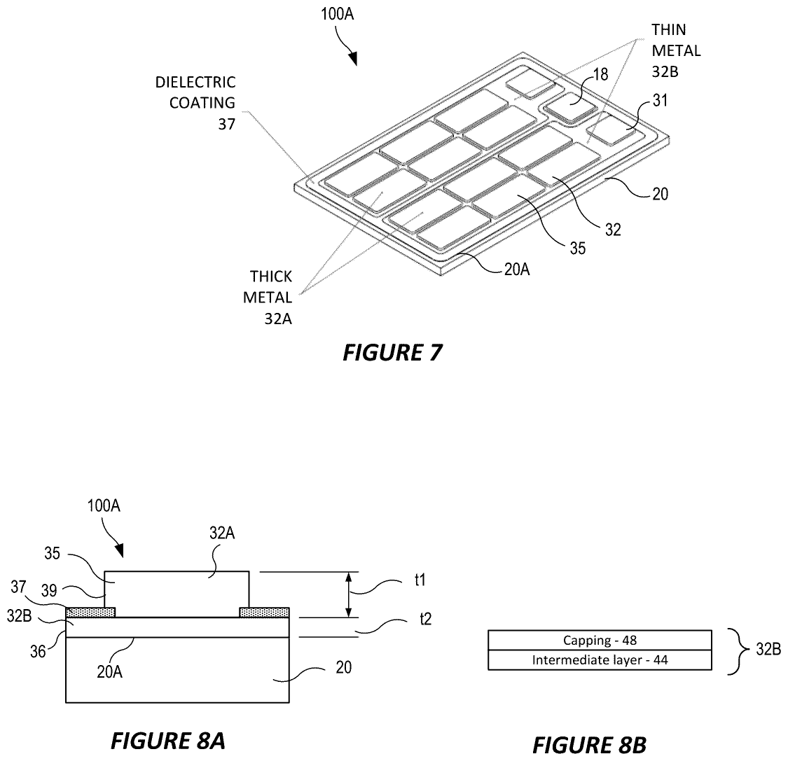

To address the issue of wafer warpage while delivering the benefits of thick metallization, some embodiments apply thick metal selectively using multiple masked deposition processes. That is, instead of applying thick metal on all conductive surfaces, the thick metal is applied selectively only where it is needed. These localized thick plateaus of metal provide buffering and robustness but are small enough that the metal loading is greatly reduced, and the expansion stresses are lessened. This approach is shown on an example power device in FIGS. 7, 8A and 8B. A section view is also presented. Note that there are many functional layers in the sectional view that are not shown for simplicity. Embodiments are described herein in the context of MOSFET power semiconductor devices. However, it will be appreciated that the inventive concepts may be applied to many different types of semiconductor devices, such as JFETs, IGBTs, diodes, and other devices.

Referring to FIGS. 7, 8A and 8B, a semiconductor MOSFET device 100A according to some embodiments includes a semiconductor die 20 on which a top side metallization 32 is formed on an upper surface 20A of the semiconductor die 20. The top side metallization 32 includes a thin metal layer 32B formed on an upper surface 20A of the die 20, and a thick metal layer 32A formed on the thin metal layer 32B. The thin metal layer 32B and the thick metal layer 32A may together form, for example, a source contact of the semiconductor device 100A. As used herein in reference to metal layers, the terms “thick” and “thin” refer to the dimension of the metal layer as measured in a direction normal to the surface on which the metal layer is formed, such as the upper surface 20A of the semiconductor die 20. Thus, for example, the thick metal layer 32A has a thickness t1, while the thin metal layer 32B has a thickness t2 as illustrated in FIG. 8A.

Referring still to FIGS. 7, 8A and 8B, a dielectric coating 37 may be formed on portions of the upper surface 20A of the die 20 not covered by the thick metal layer 32A. The thick metal layer 32A may include a metal, such as copper or aluminum, that is suitable for connection by a wire bond (not shown). The thick metal layer 32B is formed as a plurality of discrete thick metal regions on the thin metal layer 32A. The discrete thick metal regions may serve as bond pads 35 of the device 100A. That is, the bond pads 35 are physically separated from one another and are mechanically and electrically connected to one another only through the thin metal layer 32B. The bond pads 35 include a plurality of source wire bond pads, or source bond pads. The bond pads 35 also include a source kelvin bond pad 31 to facilitate a source kelvin connection to the device input signal line as shown in FIG. 2.

The thick metal layer 32A is formed where needed for a desired performance, interconnection scheme, and interconnection material. It may be deposited through similar processes as the thin metal layer 32B. A mask or similar may be used to only apply the metal where desired to form the bond pads 35. The bond pads 35 may also be formed by plating a thick layer of metal over the thin metal layer 32B and etching or selectively depositing the plated metal to form the bond pads 35. Plating is a practical and cost effective to form relatively thick layers.

The thin metal layer 32B may have a thickness of about 1 micron to 5 microns, while the thick metal layer 32A may have a thickness of about 20 microns or more. In some embodiments, the thick metal layer 32A may have a thickness that is at least 1.5 times the thickness of the thin metal layer. In further embodiments, the thick metal layer 32A may have a thickness that is at least 2 times the thickness of the thin metal layer. In still further embodiments, the thick metal layer 32A may have a thickness that is at least 5 times the thickness of the thin metal layer. In still further embodiments, the thick metal layer 32A may have a thickness that is at least 10 times the thickness of the thin metal layer. In still further embodiments, the thick metal layer 32A may have a thickness that is at least 20 times the thickness of the thin metal layer.

By forming a thin layer of metal on the semiconductor die 20, the design rule for manufacturing the semiconductor die 20 may be tightened, which means that it maybe possible to form smaller or more dense features in the semiconductor die 20 than would be possible if only a single thick metal stack were formed thereon. It will be appreciated that the design rule for a semiconductor die determines how closely or densely features can be formed on the die. When the initial metal layer on the die is thick, a larger design rule is required due to lateral variations in the thick metal layer to discourage the initial metal layer from undesirably contacting unintended features on the die. According to some embodiments, by forming an initial metal layer as a thin layer 32B having a thickness of less than 5 microns, the design rule for the semiconductor die may be reduced.

As seen in FIG. 8A, the thick metal layer 32A may be formed so that the side walls of the bond pads 35 are inwardly recessed from the sidewalls of the thin metal layer 32B. That is, the outside edges 39 of the bond pads 35 may not reach all the way to the outside edges 36 of the thin metal layer 32B. As used herein with respect to metal layers, the term “edge” refers to the outer sidewall, outer surface or outer portion of the metal layer.

Referring to FIG. 8B, the thin metal layer 32B may be part of a first layer metal stack which typically includes a capping metal 48 and one or more intermediate layers 44 between the capping layer 48 and the semiconductor die 20. These layers may be deposited through a number of processes, including but not limited to evaporation, sputtering, plating, and the like.

The capping layer 48 may be a metal that is metallurgically compatible with the desired material for the thick metal layer 32A, which typically includes copper but may include aluminum. For example, the capping layer 48 may include copper, aluminum copper, aluminum, or any other suitable metal.

The thick metal layer 32A may include a material with a high mechanical strength. Generally, copper may be desirable to use for the thick metal layer 32A, due to its mechanical strength and/or hardness, to support the formation of copper wire bonds to the bond pads 35. The force of forming a wire bond to the bond pad 35 may displace softer metals, such as aluminum, pushing it to undesired locations on the die.

Copper is also desirable for use as the thick metal layer 32A due to its high electrical and thermal conductivity. However, in some cases other metals may be desirable. The thick metal layer 32A may be left bare, or in some cases it may be further plated with a more oxidation resistant material such as nickel, palladium, gold, etc.

The intermediate layer 44 may include a diffusion barrier layer which serves the purpose of obstructing inter-diffusion of soluble metals. As an example, if the capping layer 48 contains copper, then without a diffusion barrier, copper may spread into and contaminate the underlying metals and also likely diffuse into the underlying insulating layers, interconnects, gate oxides, and substrate of the die 20. This ultimately may inhibit or destroy the function of the device 100A. Adding an insoluble diffusion barrier layer of, for example, TiN may obstruct this from occurring. The intermediate layer may include other layers, such as adhesion layers, seed layers, etc.

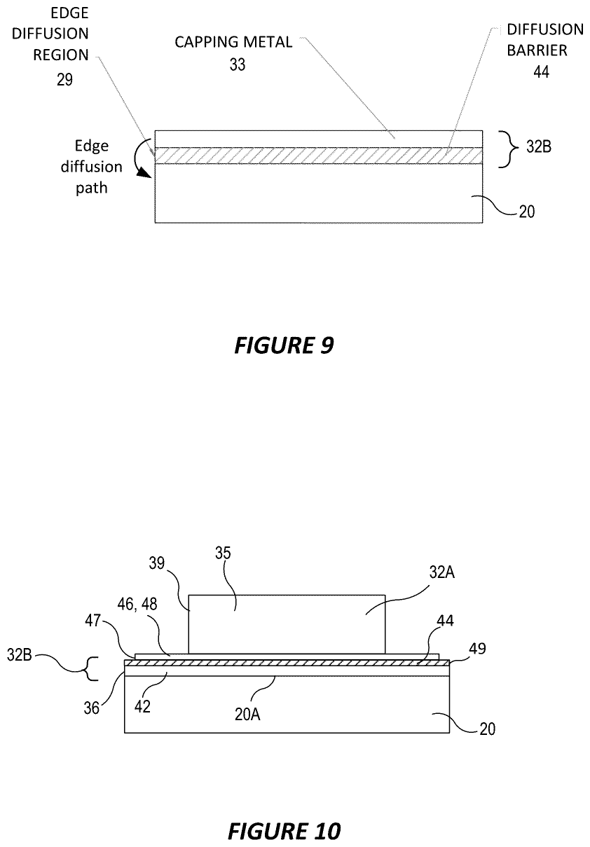

Even if a diffusion barrier is used, however, diffusion may still be possible at the edges of the interface. That is, metal can diffuse around the edges where there is no diffusion barrier in the vertical direction. This is illustrated in FIG. 9, which shows a capping layer with regions 29 where edge diffusion could occur (left) from a capping layer 33 to the die 20.

FIG. 10 illustrates a selective approach in which the seed layer 46 and capping layer 48 are inset from the edges of the diffusion barrier layer 44. That is, recessed edges 47 of the seed layer 46 and capping layer 48 do not extend all the way to the edge 49 of the diffusion barrier layer 44. This may reduce the possibility of edge diffusion from the seed and copper layers 46, 48 into the die 20.

Moreover, the bond pad 35 of the thick metal layer 32A is inset such that the edge 49 diffusion barrier layer 44 extends past the edge 39 of the bond pad 35 to further reduce the possibility of edge diffusion from the bond pad 35.

### Top Side Embodiments

There are many implementations of top side metallization using the selective metal approach according to various embodiments of the inventive concepts. The specific approach could be tailored to accommodate a number of factors, including one or more of device size, device aspect ratio, device shape, pad size, interconnection method, interconnection material, bonding direction, bonding pattern, package features and/or product application.

Example top side features are described in the following for a reference device. These may be used by themselves or in combination with back side features depending on many of the factors listed above. Interconnection in the examples includes signal and power bonds. Individual interconnection bonds for each thick pad are illustrated. However, the pads may be stitch bonded together as well, which is not pictured but is also possible with this method.

Note that a specific implementation is not limited to these examples, and ultimately is driven by product and application factors. Also note that there is an unused bond pad in the examples (on the upper left side) that could be used as an alternative site for source kelvin bonding. It could also be used as a bonding site for on-chip sensors like temperature, current, and the like. Additional bonding pads would be configured to match the specific needs of that particular device.

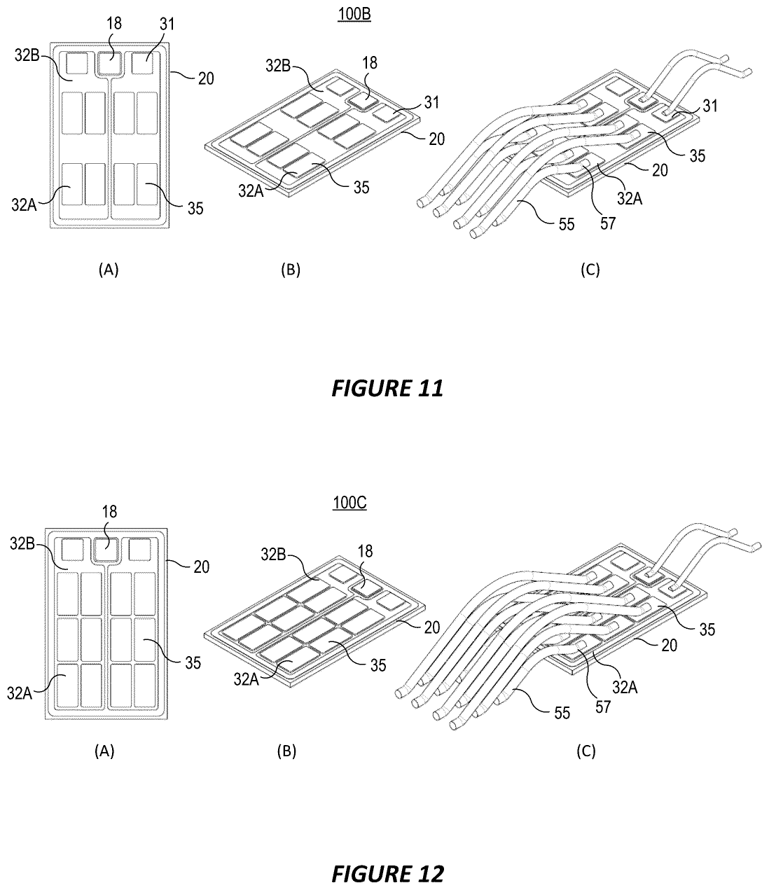

FIG. 11 depicts an example top side pattern for wire bonding in a device 100B including a plurality of bond pads 35 on a thin metal layer 32B that provides source contacts for the device 100B. The bond pads 35 may be square, rectangular or any other shape as desired to provide sufficient room for a wire bond foot 57 of a wire bond 55 that is connected to the bond pad 35. In the device 100B, the bond pads 35 are formed in pairs and arranged to allow individual wire bond connections 55 thereto. The bond pads 35 have a rectangular shape with an aspect ratio of long side to short side that is selected to permit the bond pads 35 to receive a wire bond connection 55 that extends in a direction parallel to the long side of the bond pad 35 and directly away from the gate pad 18.

In some cases, as much of the device top side area as possible is used for bonding. FIG. 12 depicts an example ‘fully loaded’ top side pattern for a device 100C with a dense arrangement of bond pads 35. The shapes of the bond pads 35 may be square or rectangular to provide sufficient room for the wire bond foot 57.

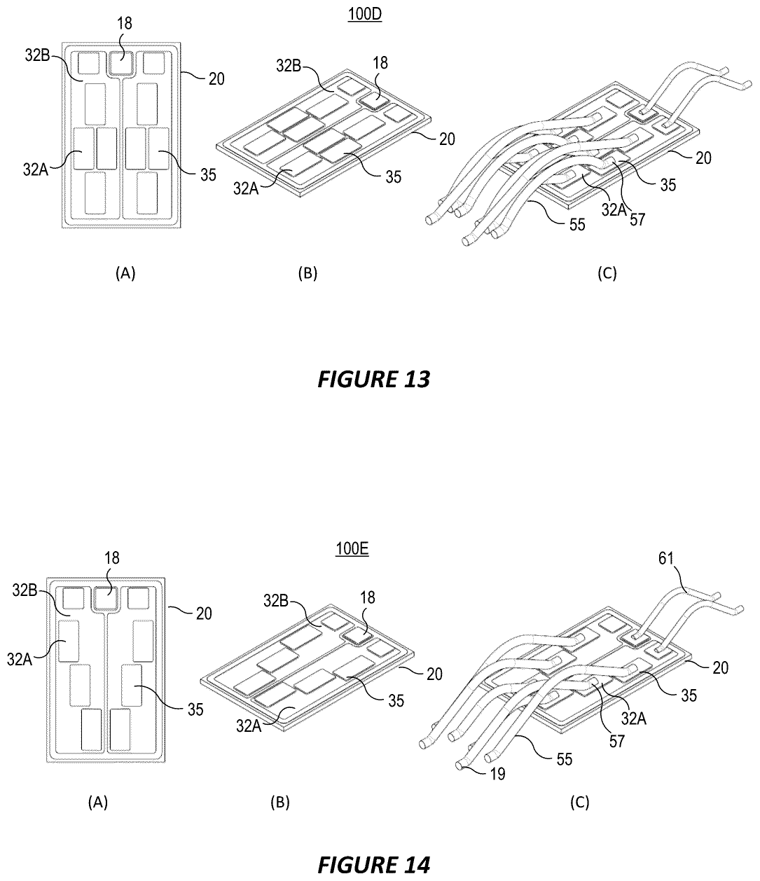

In some cases, the pads could be staggered or not in-line. This could be used to match a specific bonding pattern, or to specifically address a warpage or stress issue, such as removing thick metal from the corners. FIG. 13 depicts a device 100D having a example staggered top side pattern of bond pads 35. The shapes of the bond pads 35 may be square or rectangular to provide sufficient room for the wire bond foot.

Another staggered pattern is depicted in FIG. 14 where the bond pads 35 of a device 100E are staggered in a diagonal line such that wire bonds 55 are not stacked. This could find use for wire bonding processes with less capability to form precise loop heights.

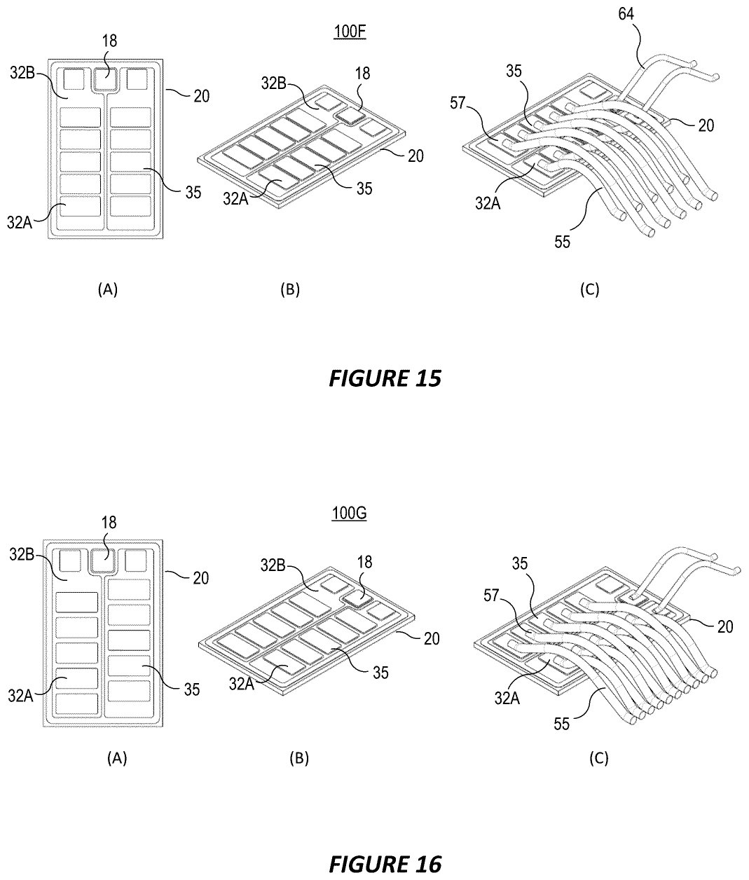

In many package types, the gate wire bonds 64 (i.e., those formed to the gate contact and that carry a signal) are formed in one direction, and the source wire bonds 55 (i.e., those formed to a source contact and that carry power) are formed in another direction. Often, they are orthogonal to each other. In other cases, they are bonded off in arbitrary angles. The size and location of the thick square or rectangular pads can be arranged to accommodate these bond angles. An example pattern for orthogonal bonding for a device 100F is illustrated in FIG. 15. In particular, in the device 100F, the source wire bonds 55 are formed in an orthogonal direction relative to the gate wire bond 64. The rectangular bond pads 35 are arranged so that the source wire bonds 55 are parallel to the long sides of the bond pads 35.

Staggered angled or orthogonal patterns may also find use as shown in FIG. 16, which illustrates a device 100G. Here, the bonds are staggered on device such that the loop height of each bond may be the same. That is, the bond pads 35 are arranged so that no source wire bond 55 must extend over or across another source wire bond 55. This arrangement may be useful in packages where the height is limited, or the inductance of the wire bonds is paramount.

The bond pads 35 may typically be sized to match the bond foot at the desired bonding angle.

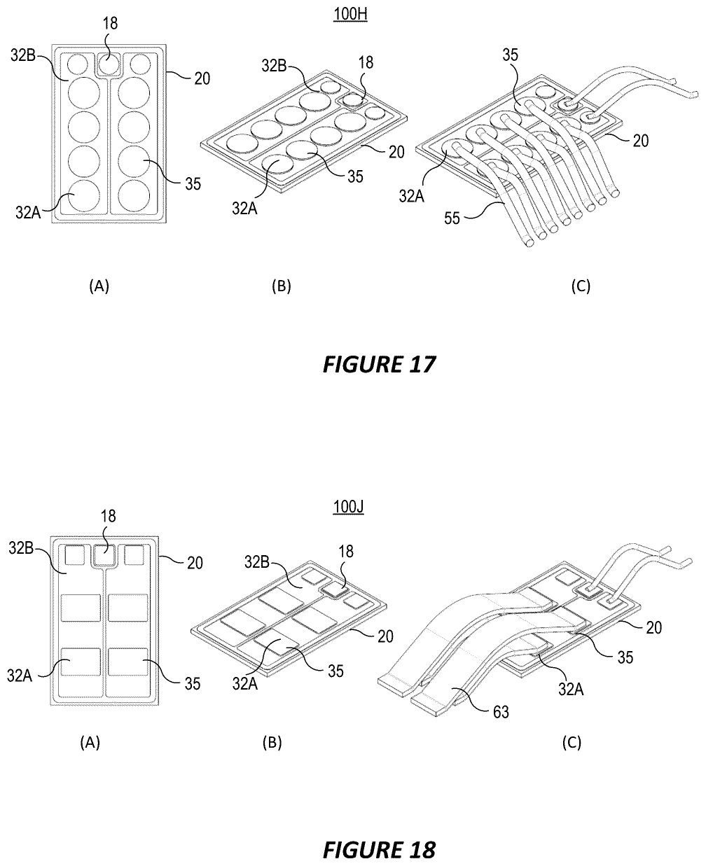

In some embodiments, the pads bond pads 35 may have a shape that is non-rectangular. For example, the bond pads 35 may be circular in shape so that bonding at any angle would be possible, such as illustrated in the device 100H FIG. 17. Circular features, in particular, may impart less stress to the substrate, thereby reducing warpage.

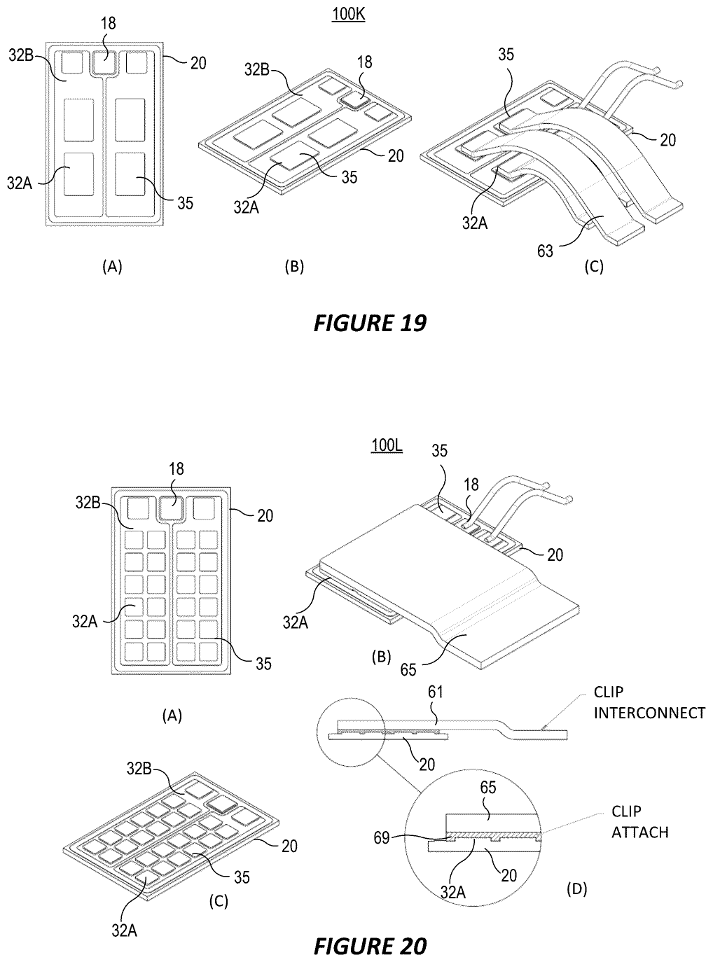

Selective metallization is also highly compatible with ribbon bonding. With ribbons, a rectangular cross section is used for the interconnect instead of a circular wire. This significantly enhances the ampacity and ruggedness of the bond. Examples for in-line and orthogonal bonding are shown in FIG. 18 and FIG. 19. For example, FIG. 18 illustrates a device 100J in which ribbon connections 63 are made to the bond pads 35. FIG. 19 illustrates a device 100K in which ribbon connections 63 are made to the bond pads 35 and extend in a direction that is orthogonal to the direction of the wire bond to the gate contact pad 18.

Note that a circular cross section may be used for the gate signal bonds to the gate pads 18, as pictured, since they are not carrying high currents. They may also be square or rectangular in cross section, however, in some applications where the robustness of that shape of wire is needed.

Top side enhancements are not limited to wire and ribbon interconnects. For example, using a three-dimensional structure clip attach structure may also improve the reliability and ruggedness of a metallurgical bond (solder, sinter, etc.) or an adhesive bond (epoxy, etc.). Here, the three-dimensional structure acts as an anchoring feature. The three-dimensional structure adds significant strength to the attach in comparison to two flat surfaces bonded together. An example surface intended to provide structure to enhance soldering is shown in FIG. 20, which illustrates a clip interconnect 61 that is soldered to the top side metal layer 32 that includes a plurality of bond pads 35 on a thin metal layer 32B. The clip interconnect 61 is connected to the top side metal layer 32 via a solder connection 69.

The specific implementation of an enhancing surface for a clip attach will depend on the size, layout, and aspect ratio of the device and the design of the clip. A waffled pattern, as shown in FIG. 20, could be used. Other patterns such as stripes, dots, hatches, and the like could also find usage in some embodiments.

A clip interconnect 61 may also be used for a flip chip or double-sided package. In this application, the thick metal would act as a physical spacer to provide sufficient room for encapsulation or underfill to cover critical voltage blocking regions such as the edge termination.

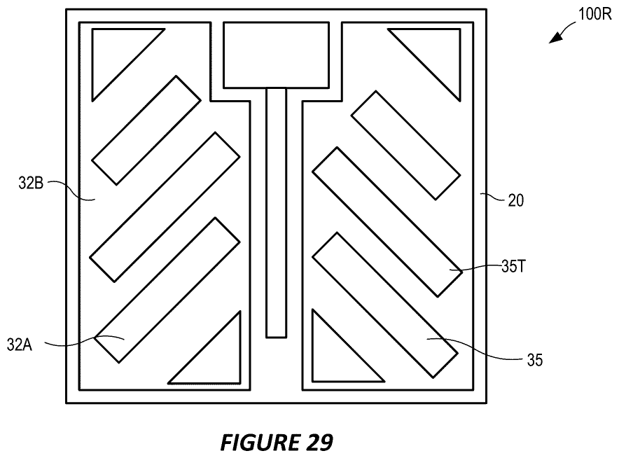

FIGS. 27, 28 and 29 illustrate embodiments in which the top side metallization includes diagonalized bond pad arrangements. Such arrangements may impart lower stress to the underlying semiconductor structure as compared to the use of only orthogonal bond pads.

In particular, FIG. 27 depicts an example top side pattern for wire bonding in a device 100P including a plurality of bond pads 35 on a thin metal layer 32B that provides source contacts for the device 100P. The bond pads 35 may be square, rectangular or any other shape as desired to provide sufficient room for a wire bond foot 57 of a wire bond 55 that is connected to the bond pad 35. In the device 100B, the bond pads 35 are formed as diagonal regions on the semiconductor die 20 and arranged to allow individual wire bond connections 55 thereto. The bond pads 35 have a rectangular shape with an aspect ratio of long side to short side that is selected to permit the bond pads 35 to receive a wire bond connection 55 that extends in a direction parallel to the long side of the bond pad 35 and away from center of the die 20 at oblique angles. Additional triangular bonding regions 35T may also be provided, for example, for source kelvin connections.

FIG. 28 depicts an example top side pattern for wire bonding in a device 100Q including a plurality of bond pads 35 on a thin metal layer 32B that provides source contacts for the device 100Q. The bond pads 35 may be square, rectangular or any other shape as desired to provide sufficient room for a wire bond foot 57 of a wire bond 55 that is connected to the bond pad 35. In the device 100N, the bond pads 35 are formed as diagonal cross-shaped regions on the semiconductor die 20 and arranged to allow individual wire bond connections 55 thereto. The bond pads 35 have a rectangular shape with an aspect ratio of long side to short side that is selected to permit the bond pads 35 to receive a wire bond connection 55 that extends in a direction parallel to the long side of the bond pad 35 and away from center of the die 20 at oblique angles. Additional triangular bonding regions 35T may also be provided, for example, for source kelvin connections.

FIG. 29 depicts an example top side pattern for wire bonding in a device 100R including a plurality of bond pads 35 on a thin metal layer 32B that provides source contacts for the device 100R. The bond pads 35 may be square, rectangular or any other shape as desired to provide sufficient room for a wire bond foot 57 of a wire bond 55 that is connected to the bond pad 35. In the device 100N, the bond pads 35 are formed as diagonal regions on the semiconductor die 20 in a chevron pattern and arranged to allow individual wire bond connections 55 thereto. The bond pads 35 have a rectangular shape with an aspect ratio of long side to short side that is selected to permit the bond pads 35 to receive a wire bond connection 55 that extends in a direction parallel to the long side of the bond pad 35 and away from center of the die 20 at oblique angles. Additional triangular bonding regions 35T may also be provided, for example, for source kelvin connections.

### Back Side Embodiments

There are many implementations of back side metallization using a selective metal approach according to some embodiments. The specific approach could be tailored to accommodate a number of factors, including one or more of device size, device aspect ratio, device shape, pad size, interconnection method, interconnection material, bonding direction, bonding pattern, package features and/or product application.

Example back side features are described in the following for a reference device. These may be used by themselves or in combination with top side features depending on many of the factors listed above. Note that specific implementation is not limited to these examples, and ultimately is driven by product and application factors.

Thicker metal on the device back side can provide benefits such as thermal buffering, added mechanical robustness, and compatibility with some attach methods (diffusion bonding, for example). Similar to the top side metallization, warpage issues limit what is practical. A selective approach is an attractive solution, as the metal plane can be broken up such that the copper fields have room to expand without creating warpage in the wafer.

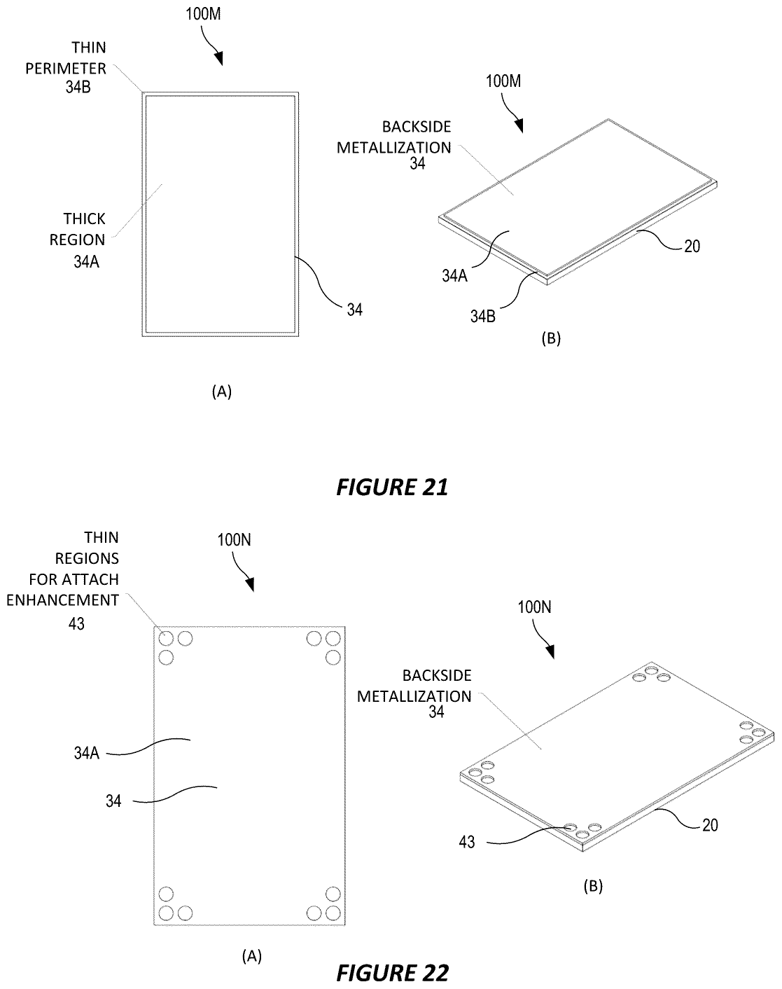

FIG. 21 illustrates an example of a device 100M in which a metal layer 34 includes a thick portion 34A (e.g., of copper) is provided over most of the device back side. The metal layer 34 includes a thin portion 34B is formed as a perimeter around the outside of the thick portion 34A. Here, each die 20 would have its own thick region, while the entire wafer back side would be broken up such that there is not a single large field of thick metal. Note that in some cases, the thick portion 34A of the metal layer 34 could fill the entire back side, while the thin portions 34B are in the dicing streets between devices.

In some embodiments, the thick portion 44A and the thin portion 34B of the metal layer 34 are provided by separate layers that are formed from different metals. For example, the thick portion 34B may be copper, while the thin portion may be aluminum copper.

Additionally, providing thicker metal on both sides of the wafer can manifest in a stress balance such that the warpage induced by the patterns could ‘equal out’, resulting in a net flattening effect on the final distorted shape.

The selective pattern could also be used as a means to enhance the reliability of the device attach. For example, thin regions in the corner could be used to increase the surface area of a solder bond, as it is known that device corners may be a weak spot at which metal delamination may occur. As shown in FIG. 22, the thin portion 34B comprises recessed features 43 that are placed in the corners of the thick metal layer 34A of a back side metallization 34 of a device 100N. During processing, molten solder would flow into the recessed features 43, filling them entirely. This may anchor and strengthen the solder bond in the region where delamination is most likely to occur. Similar benefits could be envisioned for other attach materials and processes, such as sintering, diffusion bonding, adhesive bonding, and the like. The recessed features 43 may be circular as shown in FIG. 22, or may have any other peripheral shape (e.g., square, rectangular, hexagonal, etc.).

Recessed features could also be used as a manner of bond line control. In this case, pressure during the attach process could ‘flatten out’ the bond line by pressing the thick regions directly against the power substrate.

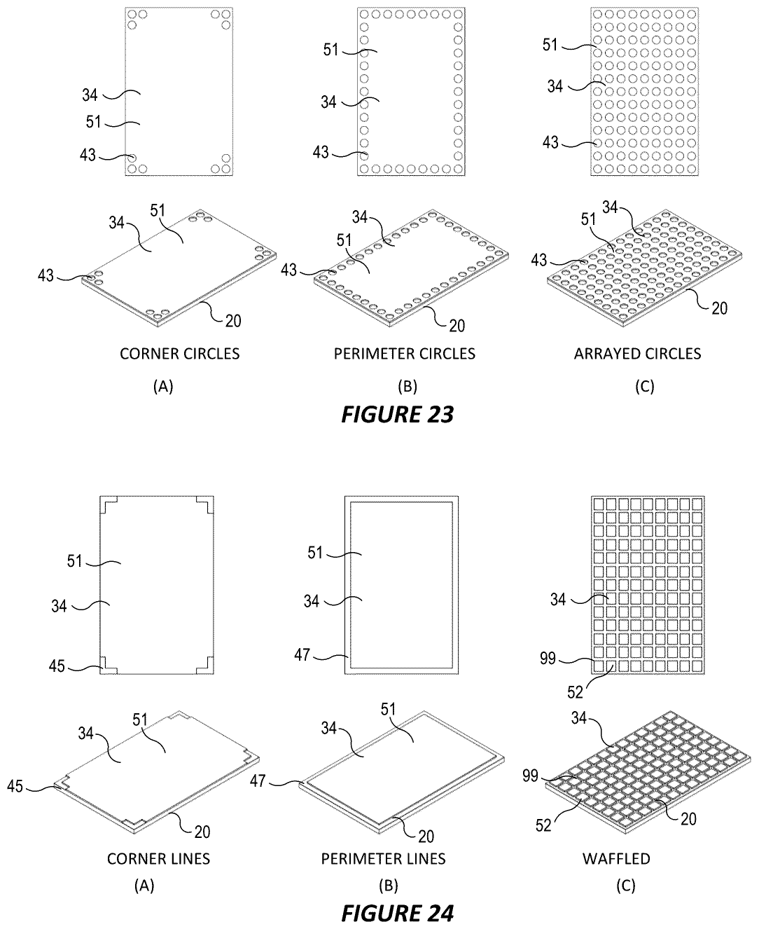

FIG. 23 shows back side enhancements of a device using thin circular features 43. The location and pattern can be driven by a number of factors. For example, FIG. 23(A) illustrates a device including three thin circular features 43 in each corner. FIG. 23(B) illustrates a device including thin circular features 43 along the sides. FIG. 23(C) illustrates a device including thin circular features 43 arranged in a two-dimensional array of rows and columns.

Thin corner and edge features add robustness in the attach layers where stress is the highest, while leaving the central area thick for optimal heat spreading/thermal performance. An arrayed approach could get the most rugged attach at the tradeoff of reduced thermals.

Thin circular features could potentially be of varying diameter. In this implementation, the diameter of the feature and the associated strengthening/anchoring geometry could vary based on the stress pattern of the device. For example, smaller diameter circles in the middle and larger diameter circles in the corners.

Linear features could also be beneficial, particular on the perimeter. FIG. 24 illustrates example linear corner, perimeter, and array features.

FIG. 24(A) illustrates a device including three recessed features 45 in each corner. A thick metal region 51 covers the center of the back side of the device. FIG. 24(B) illustrates a device including thin linear recessed features 47 along the perimeter of the die 20 around the thick metal region 51. FIG. 24(C) illustrates a device including thin linear recessed features 99 arranged in a two-dimensional array of rows and columns that define thick metal regions 52 therebetween. As shown in FIG. 24(C), in some embodiments, the back side metallization may include a metal layer on the back side semiconductor die, where the metal layer has a first thickness, and at least two discrete pads on the metal layer, wherein the at least two discrete pads have a second thickness that is larger than the first thickness.

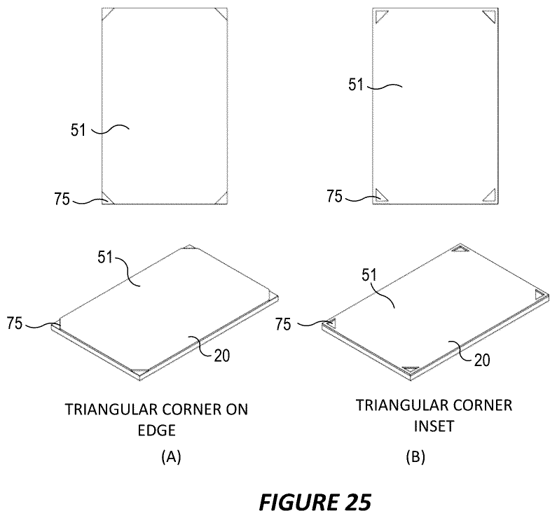

FIG. 25(A) illustrates a device including triangular recessed corner features 75 at the corners of the die 20. A thick metal region 51 covers the center of the back side of the device.

Depending on process and method, edge linear recessed features may have challenges in wafer dicing or device segmentation. In this case, the triangular recessed features 75 could be inset inside of the corners of the thick metal region 51 as shown in FIG. 25(B).

Many of the features described above can be used in combination. For example, the recessed circular features 43 shown in FIGS. 22 and 23 and/or the recessed corner features 45, 75 shown in FIGS. 24 and 25 may be using in combination with the thin perimeter metallization 34B shown in FIG. 21. Any other similar combination of features may be used depending on the needs of the application.

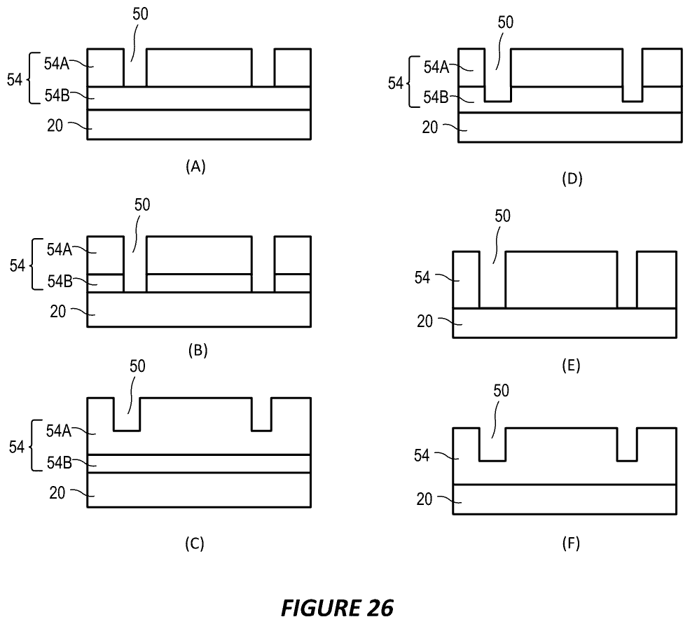

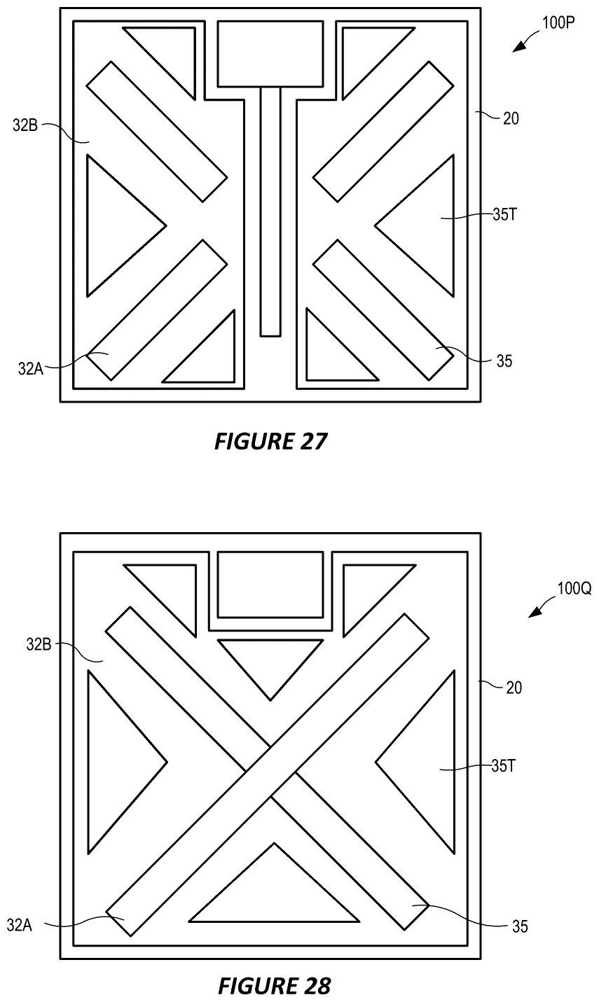

FIG. 26 illustrates configurations of metal layers and recessed features according to various embodiments. Each structure includes a plurality of recessed features 50, which may correspond to one or more of the recessed features 43, 45, 47, 75 described above in connection with FIGS. 21-25. For example, FIGS. 26(A), 26(B), 26(C) and 26(D) illustrate embodiments in which a back side metal layer 54 includes a first metal layer 54A and a second metal layer 54B on the semiconductor die 20, where the first metal layer 54A is on the second metal layer 54B and the second metal layer 54B is on the semiconductor die 20. The first metal layer 54A may correspond to the thick region 34A shown in FIG. 21 while the second metal layer 54B may correspond to the thin region 34B shown in FIG. 21.

As shown in FIGS. 26(A), 26(B), 26(C), and 26(D), the recessed features 50 may extend only through the first metal layer 54A (FIG. 26(A)), completely through the first metal layer 54A and the second metal layer 54B (FIG. 26(B)), partially through the first metal layer 54A (FIG. 26(C)), or completely through the first metal layer 54A and partially through the second metal layer 54B (FIG. 26(D)).

FIGS. 26(E) and 26(F) illustrate embodiments in which a back side metal layer 54 includes a single metal layer. As shown in FIGS. 26(E) and 26(F), the recessed features 50 may extend completely through the metal layer 54 (FIG. 26(E)) or partially through the metal layer 54 (FIG. 26(F)).

Moreover, in any of the described embodiments, a single device may include one or more recessed features 50 that extend completely or partially through a given layer 54, 54A, 54B and one or more other recessed features 50 that do not extend completely or partially through the given layer 54, 54A, 54B.

Some further embodiments described herein provide various techniques and/or geometries for forming top side and back side metallizations for semiconductor devices. Some embodiments described herein may reduce damage in the back side metallization during wafer singulation processes (sawing, dicing, laser scoring, and the like).

Moreover, some embodiments described herein may reduce imperfections in the back side metal edge quality (edge tags, peeling, etc.) due to metal tearing during the wafer singulation process.

Some embodiments described herein may reduce stress concentrations at metallization corners through edge transition features, and/or smooth out stress gradients to distribute the peak stress regions across a larger area instead of a single point.

Some embodiments described herein may reduce damage in the back side metallization during wafer singulation processes (sawing, dicing, laser scoring, and the like).

In some embodiments, an offset region on the back side attach layer may act as a mechanical anchor to enhance adhesion of an encapsulation or mold compound.

Semiconductor devices are fabricated in the format of a wafer in which many chips are manufactured on a single semiconductor substrate. Numerous manufacturing processes are used in the fabrication of semiconductor devices, including crystal growth, epitaxial growth, deposition of various materials (metals, glasses, ceramics, dielectrics, etc.), patterning using various methods, etching or material removal using various methods, singulation, and the like.

The devices are separated from the wafer in a process known as singulation. Generally, this involves a mechanical sawing or dicing operation or a lasering process in which a laser ablates the material away. to separate the devices. Lasering may involve a variety of methods, including full depth, partial depth and perforation, as described below.

In a full depth laser singulation process, the laser scribes completely through the wafer surface in lines, often in a series of passes or layers. Chips are fully singulated at this stage, and further separated through a separate process such as tape expansion.

In a partial depth laser singulation process, the laser scribes partially through the wafer surface in lines, often in a series of passes or layers. Chips are not fully singulated at this stage and are ‘snapped’ apart through a separate process such as tape expansion, mandrel bending, etc.

In a perforation laser scribing process, the laser scribes completely or partially through the wafer surface in patterns, such as a series of dots, often in a series of passes or layers. Chips are not fully singulated at this stage and are ‘snapped’ apart through a separate process such as tape expansion, mandrel bending, etc.

The physical material that is removed as a result of singulation is generally referred to as ‘kerf’. The amount, or width, of kerf differs depending on the singulation process. The path of the kerf is generally referred to as the ‘street’. In the case of a wafer, the streets are typically arranged as a linear grid in both directions, but in principle could follow any arbitrary geometric pattern. Material in the kerf is sacrificial and lost during the singulation processes. Accordingly, processes which reduce the amount of kerf needed, such as laser dicing, may increase the amount of usable material for devices on the wafer.

Generally, on the wafer top side, the kerf region is left blank, (i.e., is not covered with a metal), with a tolerance, such that minimal damage to the sensitive semiconductor structure or edge termination may be introduced during singulation. However, the wafer back side, which for power devices is fully metallized, typically has no such removal for kerf. The metal region is cut through in the same process as the substrate. That is, dicing streets are not conventionally formed on the back side of the wafer, and the back side metallization is cut through in the same process as the substrate. This is illustrated for a generic wafer and generic array of devices in FIG. 230. Note that the scale the figure may be exaggerated to show detail, and the size and shape of the wafer differs depending on wafer source, fabrication processes, and the like.

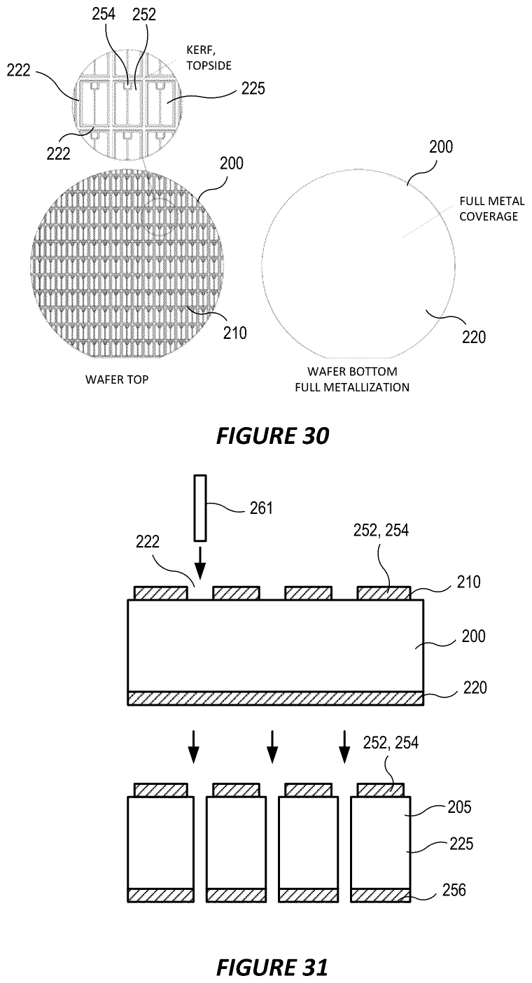

Referring to FIG. 30, a semiconductor structure, such as a wafer 200 has a top side metallization 210 on a first (front) side thereof and a back side metallization 220 on a second (back) side that is opposite the first side. The back side metallization 220 is a continuous layer of metal on the back side of the wafer 200. The top side metallization 210 is a patterned layer of metal that defines a plurality of semiconductor devices 225 that are separated by dicing streets 222 in which no metallization is formed. The top side metallization 210 may define a plurality of electrical contacts, such as source contacts 252 and gate contacts 254 for MOSFET devices. It will be appreciated that other types of contacts may be formed depending on the type of electrical device being fabricated, such as drain contacts, anode contacts, cathode contacts, source kelvin contacts, emitter contacts, collector contacts, base contacts, etc.

Singulation by sawing is illustrated in FIG. 31, which shows a saw blade 261 aligned with a dicing street 222 on the wafer 200 between metal contacts 252, 254 of adjacent devices. The saw blade 261 saws through the semiconductor wafer 200 and the back side metallization 220 to singulate the individual devices 225, each having a substrate 205 on which top side contacts 252, 254 are formed. The singulation process defines back side drain contacts 256 on respective ones of the devices 225 by sawing through the back side metallization 220.

For any singulation process, there is a chance that the back side metal is damaged during the operation. Damage may manifest in a reduction of metal adhesion, flakes or missing metal in the chip area, flakes or tags that extend past the edge of the chip, cracks, and the like. This damage could occur during sawing or dicing due to dullness or vibration in the cutting tool or similar process related defect. It could occur during lasering due to improper ablation of the metal region or excessive tearing during the final separation process (tape expansion or similar). If the metal adhesion to the device is weak or otherwise flawed, that weakness may become worse after the singulation process.

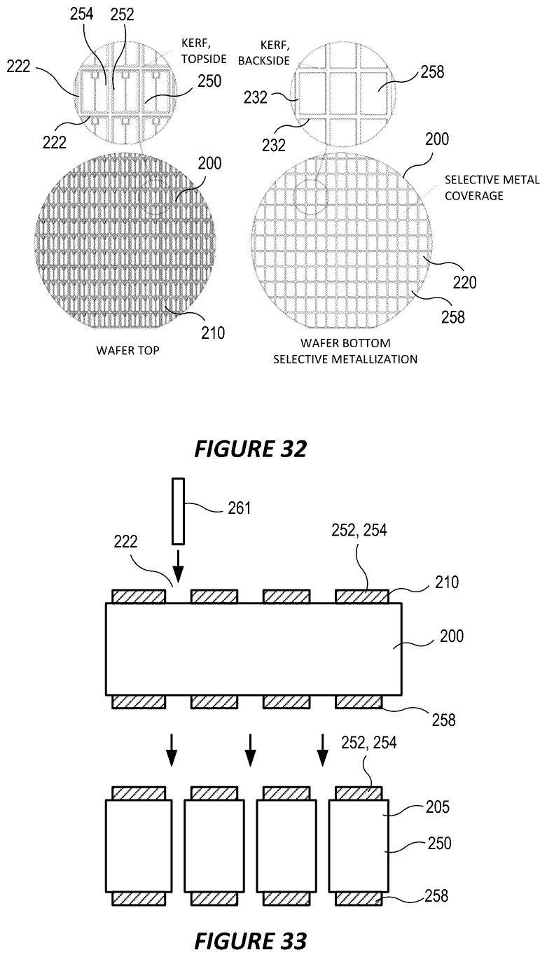

To this end, if the metal was not present in the kerf region, this damage could be reduced or prevented entirely. In turn, the shape and edge quality of the metal would be determined not by the singulation process, but as an intentional pattern. This general concept is illustrated in FIG. 32, in which portions of the back side of the wafer 200 are free of metal is removed on the backside so that the singulation process would not cut through it and cause damage.

In particular, as shown in FIG. 32, back side dicing streets 232 are provided on the back side of the wafer 200 in alignment with the top side dicing streets 222 between semiconductor devices 250. The dicing streets 232 define back side contacts 258 at the wafer level prior to dicing. Thus, in some embodiments dicing streets may be defined in both the top side metallization 210 and the back side metallization 220 of a wafer 200.

The singulation process for the wafer 200 shown in FIG. 32 is illustrated in FIG. 33. As shown there, because the dicing streets 232 are provided in the back side metallization 220, the saw blade 261 does not saw through the back side metallization 220.

The back side dicing streets 232 can be defined by an additive manufacturing process or a subtractive manufacturing process. In an additive manufacturing process, the back side metallization is deposited in such a manner that no metal is deposited in the dicing streets. For example, a deposition mask may be selectively formed on the back side of the wafer 200 to cover the dicing streets, and the back side metal may be deposited on portions of the back side 220 of the wafer 200 that are not covered by the deposition mask. In a subtractive manufacturing process, the entire back side 220 of the wafer 200 may be covered with a metal and portions of the metal corresponding to the dicing street may be selectively removed. For example, an etch mask may be formed to cover portions of the back side 220 of the wafer 200 corresponding to the back side metal contacts 258, and portions of the metal layer other than those covered by the etch masked may be etched from the wafer 200. Additive and subtractive processes for forming metal layers on semiconductor structures are well known in the art.

In addition to improving the quality and adhesion of the back side metal, other benefits can be introduced using the concept of selectively metallization the back side. Here, stress concentrations can be reduced and the stress pattern can be smoothed out by shaping the pads accordingly.

In the case of a power module, most of the attaches are conductive and metallic. Common attach techniques include soldering, brazing, and sintering. For each of these methods, the attach layer will generally conform to the shape of the pad to which it is attaching to.

Solder/Braze—In a solder/brazing process, molten material will ‘wet’ the metal surface and self-conform to its shape through capillary action. Areas where the solder are not able to wet (such as a bare semiconductor surface) the solder will pull away from.

Sinter—In a sinter process, deposited metal is heated to cause it to bond to the underlying surface. The material will only sinter to and form a bond with a compatible metal surface. Areas that are not compatible will self-sinter but not form a bond to the surface, resulting in a weak region and a crack propagation site. Accordingly, the material is applied such that it matches the surface it is being bonded to.

For the purposes of this description, any metallurgical attach method can find benefit, with the general assumption being the shape of the attach will follow the shape of the pad.

Accordingly, the shape of the pad on the device can be used to control the shape of the attach, which is fundamental in controlling the edge transitions to buffer and reduce stresses. By contouring edge transitions to better distribute stresses and reduce highly local concentrations, product reliability can be improved, and lifetime can be extended.

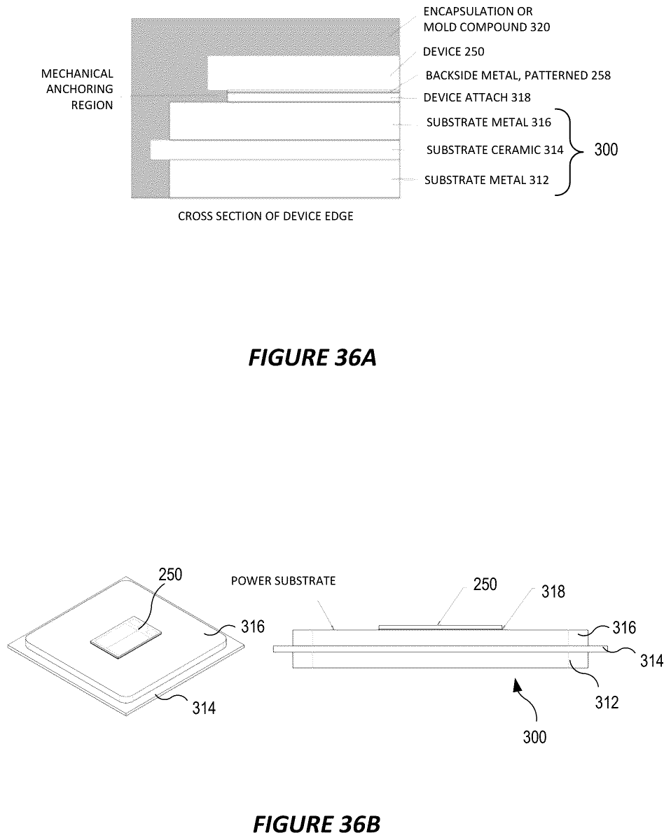

As an example, brief reference is made to FIGS. 36A and 36B, which illustrate a device 250 attached with die attach 318 comprising a conforming layer of solder to a power substrate (layered 300 that includes a lower copper, layer 312, a ceramic, and layer 314 and an upper copper), as depicted in FIG. 45. layer 315. In particular, the back side metallization 220 of the device 250 is solder bonded to the substrate 300. As the temperature rises, the copper of the power substrate 300 expands at a higher rate than the semiconductor material. The difference in expansions manifests in strain and stresses in the structure. The interfacial die attach 318 between the device and the substrate, in this case assumed to 250 and the substrate 300, which may for example be solder, bears the brunt of this stress. The stress that it sees is highest and most concentrated at the corners of the die attach where there is a high geometrical transition and where strains are also the highest.

A finite element analysis (FEA) simulation is used to compare the stress gradient at the corners for a conventional full backside coverage vs. an approach with an inset of the metallization with rounded corners for the generic example shown above. The simulation assumes the assembly is stress free at room temperature, and then reports the strains and stresses at an elevated temperature.

The resulting stress gradient under the same color scale is shown in FIG. 5. Note that the actual scale itself is not relevant here, just the comparison between the two approaches as a side by side. Red regions are of highest stress, with blue regions being lowest. The rounded corner transition ‘smooths’ out the gradient such that the highest stress regions are lesser than a corner and more evenly distributed.

Notably, failure in a device attach very often manifests as a crack or delamination in the corner. By implementing an edge transition, such as a rounded corner, in the above example back side metallization of the device, the reliability and/or lifetime of that attach can be significantly improved.

### Back Side Metallzation Shaping

Conventionally, the back side metallization extends across the device's entire back surface. When the devices are singulated from a wafer, they are diced, sawn, laser scored, or otherwise cut through. If, however, the back side metallization was patterned, then the possibility for shaping the pads to reduce stress is achieved.

The metallization coverage may be configured in various embodiments with full coverage or inset coverage as described below.

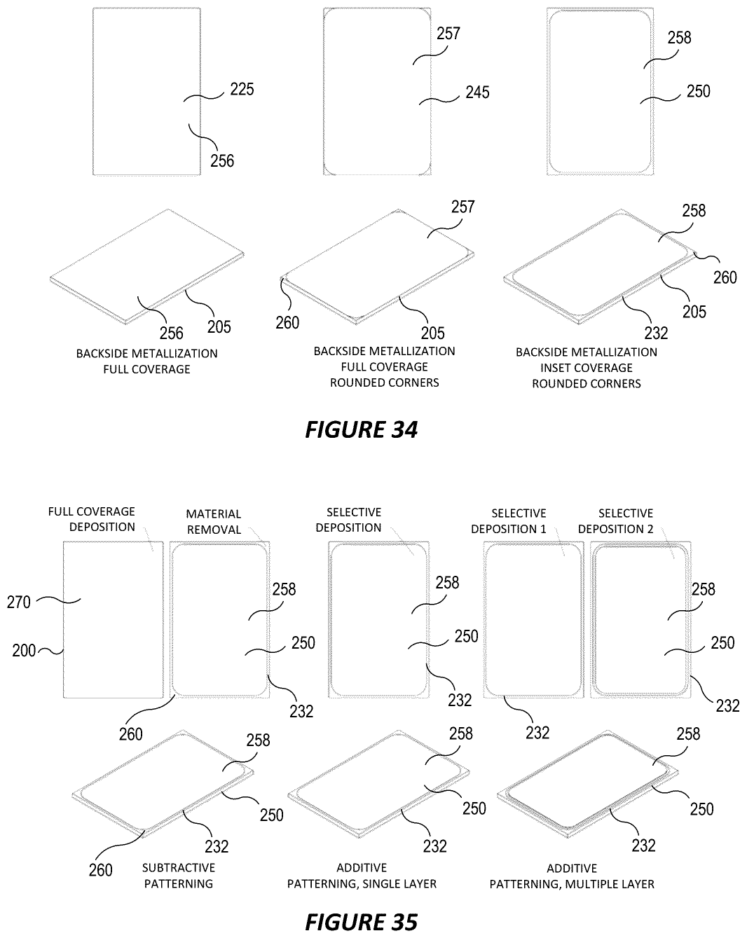

The metallization coverage may be configured in various embodiments with full coverage or inset coverage as described below. In particular, FIG. 34 illustrates some options for patterning the back side metal according to some embodiments. For comparison purposes, FIG. 34 illustrates a conventional device 225 having a back side metal contact 256 that is not patterned, i.e., that extends to the edges of the back surface of the device 225. FIG. 34 also illustrates a device 245 in which the back side metal contact 257 is patterned via an additive or subtractive manufacturing process to expose corners 260 of the device where the back side metal contact 257 is not formed. In some cases, the metal contact 257 may be rounded near the corners of the device. As noted above, mechanical stress may be highest near corners of the device. Selectively removing (or not forming) the back side metal contact 257 near the corners of the device may reduce or spread out the stress, resulting in fewer stress-related failures such as cracking or delamination.

FIG. 34 also illustrates a device 250 in which the back side metal contact 258 is patterned via an additive or subtractive manufacturing process to expose corners 260 of the device where the back side metal contact 257 is not formed as well as sides of the device where the back side dicing streets 232 were formed. In some cases, the metal contact 258 may be rounded near the corners of the device. This is referred to herein as “inset coverage” because the back side metal contact 258 is inset from edges of the device 250.

For full coverage, the backside (e.g., device 225), the back side metallization covers the entire device back side and is cut through directly during wafer singulation.

For inset coverage, (e.g., device 250), the back side metallization is inset such that it is not cut through during wafer singulation. This would be useful in cases there the metal adhesion to the device back side is not strong enough to withstand the singulation cutting processes, or alternatively, if the singulation cutting process is too damaging to the back side metallization. An example of this would be laser dicing in which the laser process damages the adhesion of the metal or creates rough edges, such as metal tags, left over after singulation.

The two approaches with rounded corners are compared to a generic power device FIG. 6. Note that in some cases, the scale of the features is exaggerated to show detail. Specific embodiments may have more or less rounding or offsets depending on the particular device and package structure. Note that while rounded corners are shown for simplicity, other embodiments are presented in a later section.

Patterning may be implemented through a subtractive technique, an additive technique with a single layer, an additive technique with a plurality of layers, or a combination of these techniques.

In a subtractive, the full back side metallization is applied. The back side metallization is selectively removed through etching, laser scribing, and the like.

In an additive, single layer technique, a mask is used to apply back side metallization selectively and not apply metallization in regions that are ‘masked off’.

In an additive, multiple layer technique, a first layer of the back side metallization is applied, either as full coverage or selectively. Then, additional metallization is applied selectively to build a three-dimensional structure. This achieves both stress reduction at the corners as well as bond enhancement through mechanical anchoring and increased bonding contact area.

The three approaches are illustrated in FIG. 35 in the case of an inset coverage with rounded corners. In particular, FIG. 35 illustrates formation of a device back side metallization using a subtractive process and additive processes. In one example, a blanket metallization 270 is formed on a semiconductor structure, such as wafer 200, and metal is selectively removed from edges and corners of the device 250 to form dicing streets 232 and rounded corners 260.

In a single metal process, a single layer of metal is selectively deposited on a back side of the semiconductor structure other than at the edges (i.e., in dicing streets) and at the corners of the device to form a back side contact 258 on the back side of the device 250.

In a dual metal process, a first layer of metal is selectively deposited on a back side of the semiconductor structure other than at the edges (i.e., in dicing streets) and at the corners of the device 250 (selective deposition 1). A second layer of metal is then selectively deposited on the first layer of metal, again leaving the edges and corners of the substrate uncovered (selective deposition 2). The first and second layers of metal together form a single metal contact layer on the device 250.

Note that for each of these cases, there may be a number of associated processes (mask deposition, mask patterning, mask liftoff, etc.) that are not outlined, for simplicity. Note that in some cases, the scale of the features is exaggerated to show detail. Specific embodiments may have more or less rounding or offsets depending on the particular device and package structure. Note that while rounded corners are shown for simplicity, other embodiments are presented in a later section.

Patterning may also occur as a combination of techniques. For example, additive deposition followed by subtractive patterning. Specific implementation depends on the device design, wafer fabrication processes, and the structure being formed on the device.

A secondary benefit of inset approach is found in the anchoring effect the structured surface could have on surrounding encapsulation materials or mold compounds found in conventional power modules. This ‘undercut’ region provides geometry for the adhesive materials to grip to, adding strength to their attach and acting to inhibit delamination from the surfaces as they are stressed in service.

This is illustrated in FIG. 36A, which is a cross section, zoomed in view of one edge of a mounted device 250. In particular, the device 250 is mounted on a device substrate 300 formed of a first metal layer 312, a ceramic layer 314 and a second metal layer 316. The device 250 is attached to the substrate 300 with a die attach 318, such as solder, that attaches to the patterned back side contact 258 of the device 250. An encapsulation or mold compound 320 is formed over the entire structure.

Here, the die attach 318 follows the inset metal pattern, creating a small region around the perimeter where there is a region where the encapsulation or mold compound can fill in underneath the device. This additional structure creates an anchoring or locking effect on the material, enhancing its bond strength. Note that layer thicknesses in the figure are used to show the detail of this approach and may be scaled differently in many cases.

### Top Side Metallzation Shaping

Conventionally, top side metallization covers multiple terminals on the device (gate and source, in the case of a MOSFET) forming ‘pads’ of metal to bond to. The metallization covers all active areas as well as signal bonding regions, gate runners, sensors, etc. This metallization as well as the edge terminations around the perimeter of the device are covered in a protective overlay isolating material with openings to allow for electrical interconnection to the pads (wire bonds, ribbon, clips, lead frames, etc.).

In cases where a solder, sinter, or similar metallurgical attach is used on the device top side, then a similar motivation exists to reduce stress concentrations through corner transitions. Top side metallurgical attaches are common in packages where the device top sides are attached to a clip, lead frame, or power substrate. In some cases, only the power connection to the source pad is made, while the signal pads are wire bonded. In other cases, all pads are attached to.

Consequently, corner transitions in the metallization instilling a matching corner transition in the top side metallurgical attach achieves similar reliability and lifetime benefits as was demonstrated in the back side metallurgical attach.

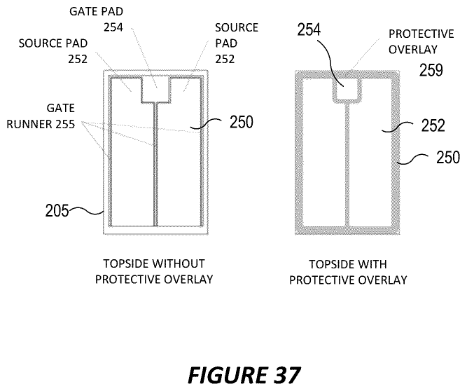

While creating a corner transition on the metal itself is not desired, as it would limit the active area of the device, the openings of the overlay metal can indeed be rounded for a similar effect as the back side metallization. The additional overlay material in the corners or edge transitions conformally shapes the metallurgical attach during processing, as described previously, such that the transition is naturally formed. Two example approaches of this technique compared to a traditional device are illustrated in FIG. 37. In particular, FIG. 37 illustrates a device 250 having a top side metallization including source contact pads 252, a gate contact pad 254 and gate runners 255 extending from the gate contact pad 254 formed on a semiconductor structure 205 that is a singulated portion of a semiconductor wafer. A protecting overlayer 259, of for example polyimide, is formed over the top side metallization. The protective overlayer 259 is patterned to expose bonding regions of the source contacts pads 252 and gate contact pad 254.

Top side surface enhancements can be achieved, for example, through an additive overlay technique or an additive multiple layer technique.

In an additive overlay technique, the protective overlay material is masked and patterned to achieve the desired corner transition feature. Effectively, this changes the ‘shape’ of the exposed metal pad without sacrificing active device area.

In an additive, multiple layer technique, an additional metallization could be applied selectively to build a three-dimensional structure. This may achieve both stress reduction at the corners as well as bond enhancement through mechanical anchoring and increased bonding contact area.

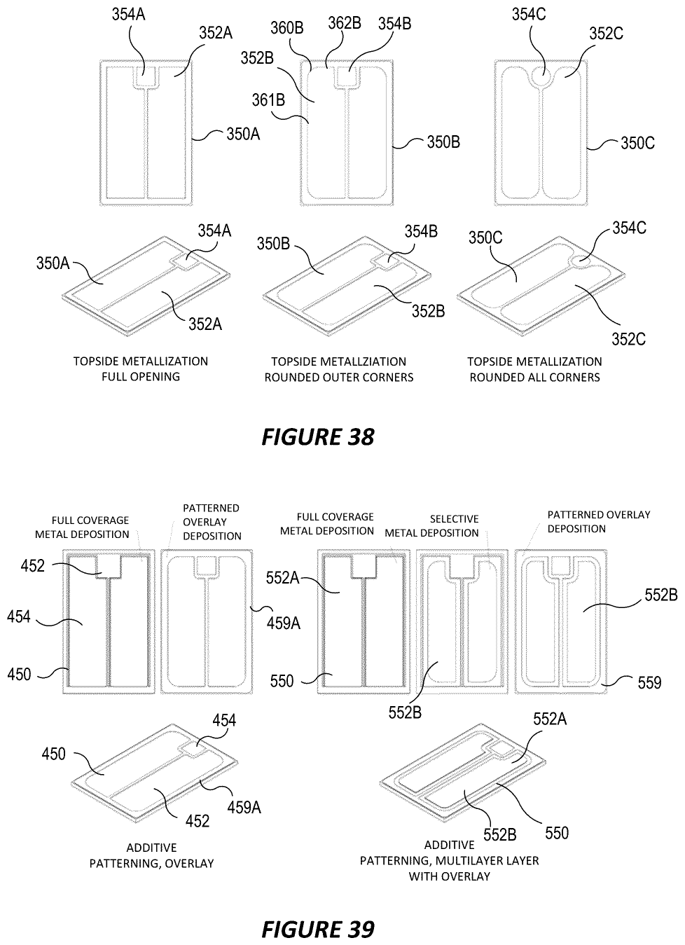

These are illustrated in FIG. 38, for reference. FIG. 38 illustrates a semiconductor device 350A having a top side metallization pattern including source contact pads 352A and gate pad 254A that are not rounded, a semiconductor device 350B having a top side metallization pattern including source contact pads 352B that are rounded and a gate pad 254A that is not rounded, and a semiconductor device 350C having a top side metallization pattern including source contact pads 352C and a gate pad 354C that are rounded.

In some embodiments, the corners of a contact pad may be rounded with a radius that is related to the size of an edge of the contact pad that forms the corner in question. For example, when a corner of the contact pad is formed by two edges of the contact pad, the corner may be rounded with a radius that is less than about one half of the length of the shorter of the two edges. In some embodiments, the corner may be rounded with a radius that is from about 10% to 50% of the length of the shorter of the two edges. In some embodiments, the corner may be rounded with a radius that is from about 30% to 50% of the length of the shorter of the two edges, and in some embodiments from about 40% to 50% of the length of the shorter of the two edges.

In some embodiments, the corners of the contact pads are rounded with a radius that is less than about one half of the length of the shortest side of the contact pad. In some embodiments, the corner may be rounded with a radius that is from about 10% to 50% of the length of the shortest side of the contact pad. In some embodiments, the corner may be rounded with a radius that is from about 30% to 50% of the length of the shortest side of the contact pad, and in some embodiments from about 40% to 50% of the length of the shortest side of the contact pad.

For example, referring still to FIG. 38, the source contact pad 352B of the device 350B includes a corner 360B that is formed at the intersection of a first edge 361B and a second edge 362B of the contact pad 352B, with the second edge 362B being shorter than the first edge 361B. The corner 360B is rounded with a radius that is equal to about 50% of the length of the second (shorter) edge 362B.

Rather than rounding the metal contacts, in some embodiments, openings in the protective overlayer that expose the underlying contact pads are rounded to reduce stress in the semiconductor device.

For example, FIG. 39 illustrates a semiconductor device 450 having a top side metallization pattern including source contact pads 452 and gate pad 454. A protective overlayer 459A is formed on the top side metallization pattern. The protecting overlayer 459A includes openings exposing the source contact pads 452 that are rounded.

In some embodiments, the corners the opening in the protective overlayer may be rounded with a radius that is related to the size of an edge of the opening in the protective overlayer that forms the corner in question. For example, when a corner of the opening in the protective overlayer is formed by two edges of the opening in the protective overlayer, the corner may be rounded with a radius that is less than about one half of the length of the shorter of the two edges. In some embodiments, the corner may be rounded with a radius that is from about 10% to 50% of the length of the shorter of the two edges. In some embodiments, the corner may be rounded with a radius that is from about 30% to 50% of the length of the shorter of the two edges, and in some embodiments from about 40% to 50% of the length of the shorter of the two edges of the opening in the protective overlayer.

FIG. 39 also illustrates a device 550 in which the source contact pad comprises a first metal layer 552A that is not rounded (i.e. that has full coverage) and a second metal layer 552B on the first metal layer 552A. The second metal layer 552B has rounded corners compared to the first metal layer 552A to provide a transition from non-rounded to rounded corners in the source metal contact pad. A protective overlayer 559 is formed over the first and second metal layers 552A, 552B to protect edges thereof.

Depending on the fabrication process and particular device design, the order of operations and associated processes (masking, exposure, demasking, etc.) may vary. For example, for a multiple layer approach, the additional metal layers could be applied before or after the overlay deposition.

The previously described examples exhibit rounded corners for simplicity. Full rounded corners are the most basic and effective approach to reduce the corner stress concentration with a smooth, constant radius.

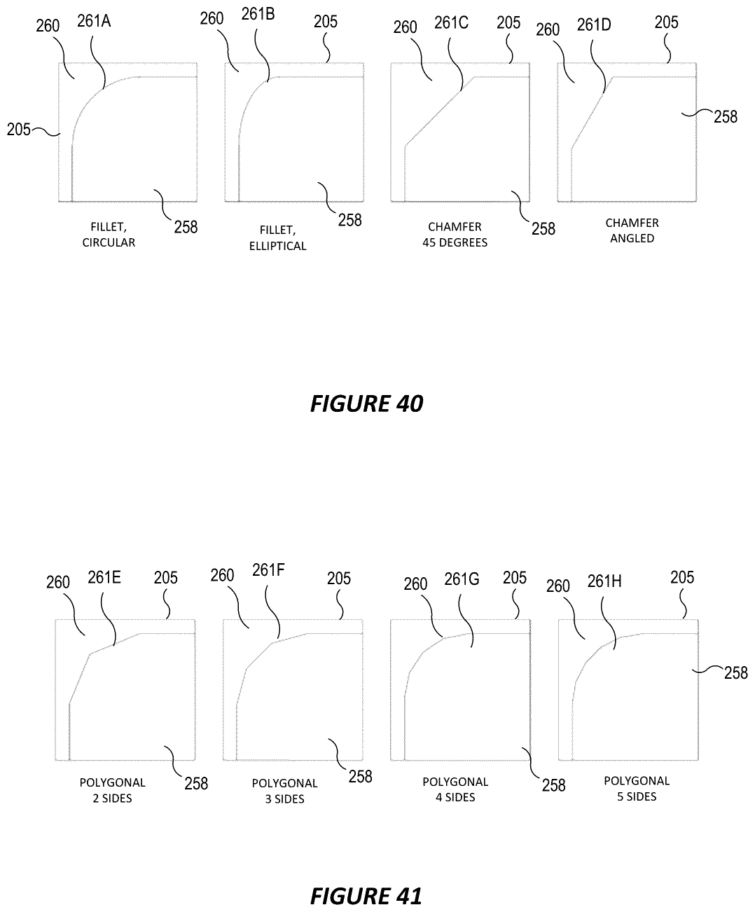

In some cases, other corner transitions may be desired based on the manufacturing processes, stress profile, device aspect ratio, etc. As an example, if the metal is selectively removed using laser ablation, it would be more effective to have a linear chamfered transition vs. rounded in some cases, as some lasers raster in straight lines. Laser scribers could be used to achieve the rounded geometry any many of the more complex designs shown below. Example corner transitions are depicted in FIG. 40. As shown therein, a metal contact 258 is formed on a semiconductor structure 205. The corners of the metal contact 258 may be rounded (261A), elliptical (261B), chamfered at a 45-degree angle (261C), or chamfered at a different angle (261D).12.

Note that the shapes could be formed with any of the previously described approaches and could be formed on the device top side and/or back side.

If a more rounded shape is needed with linear removal processes such as lasering, a rounded corner could be approximated using polygonal shapes. This approach, shown in FIG. 41, approximates a rounded corner with linear elements of increasing order, e.g., 2 sides (261E), 3 sides (261F), 4 sides (261G) or 5 sides (261H). The amount of tessellation will depend on the conditions and requirements of the implemented manufacturing process.

Patterning could find embodiments inside the metal pad also. Here, metal would be removed or deposited such that there are regions within the pad that are metal free or have additional metal thickness. These techniques could be used to improve the adhesion of the metal layer on the device and to prevent delamination when stressed.

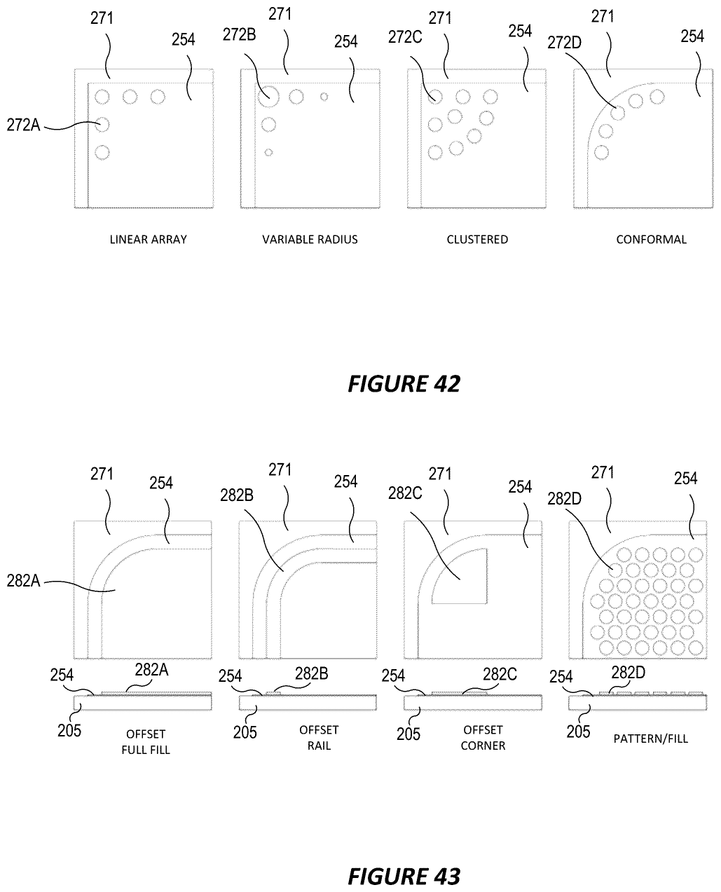

Within metallization examples are depicted in FIG. 42, which illustrates metal contact pads 254 that include holes or openings near corners 271 thereof arranged in the shape of linear arrays of holes (272A), holes having varying radii (272B), clustered holes (272C), and/or rounded corners with conformally positioned holes (272D). The metal contact pads shown in FIG. 42 may be top side metal contacts or back side metal contacts.

Within metallization examples are depicted in FIG. 14. Note that the shapes could be formed with any of the previously described approaches and could be formed on the device top side and/or back side. Also note that while circular shapes are shown, other shapes such as triangles, squares, rectangles, polygons, and slots may also find usage depending on the stress distribution that these features are intended to address.

Multiple layer structures could be added for a variety of functions, including increasing surface area to enhance bonding, creating an anchoring effect to enhance strength, and to act as a means of bond line control of the attach layer. Example of methods to implement this are shown in FIG. 43. As shown, additional metal layers may be provided on the metal contact 254 near corners 271 thereof. The metal contact pads shown in FIG. 43 may be top side metal contacts or back side metal contacts.

The additional metal layers could be placed all over (with an edge offset) (282A), as full or partial ‘rails’ (282B) following the contour, localized features (282C) in the corner of various geometries, and patterned raised features (282D) to enhance the strength all over.

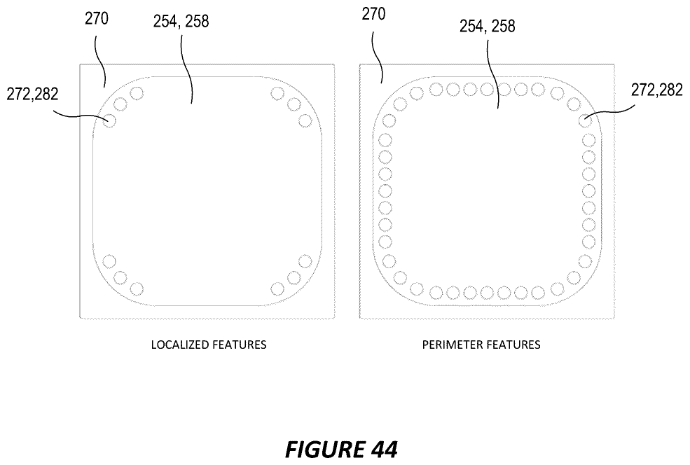

For the above single layer or multiple layer features, they could be implemented locally where the stresses are the highest. Or, alternatively, they could follow the entire perimeter of the device to reduce concentrations across the entire outer edge. The use of local vs. edge following perimeter features 272, 282 on either top side contacts 254 or back side contacts 258, respectively, is illustrated in FIG. 44. Note that the shapes could be formed with any of the previously described approaches and could be formed on the device top side and/or back side.

While the above-described power semiconductor devices and the other devices described herein are shown as being silicon carbide-based semiconductor devices, it will be appreciated that embodiments of the present inventive concepts are not limited thereto. Instead, the semiconductor devices may comprise any wide bandgap semiconductor that is suitable for use in power semiconductor devices including, for example, gallium nitride-based semiconductor devices, gallium nitride-based semiconductor devices and II-VI compound semiconductor devices.

The inventive concepts have been described above with reference to the accompanying drawings, in which embodiments of the inventive concepts are shown. The inventive concepts may, however, be embodied in many different forms and should not be construed as limited to the embodiments set forth herein. Rather, these embodiments are provided so that this disclosure will be thorough and complete, and will fully convey the scope of the inventive concepts to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout, except where expressly noted.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present inventive concepts.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used herein is for the purpose of describing particular embodiments only and is not intended to be limiting of the inventive concepts. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, elements, and/or components, but do not preclude the presence or addition of one or more other features, elements, components, and/or groups thereof.

Embodiments of the inventive concepts are described herein with reference to cross-sectional illustrations that are schematic illustrations. As such, variations from the shapes of the illustrations as a result, for example, of manufacturing techniques and/or tolerances, are to be expected. Thus, embodiments of the inventive concepts should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the inventive concepts.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present inventive concepts may include additional and/or intervening layers, structures, or elements, and/or particular layers, structures, or elements may be deleted. Although a few exemplary embodiments of the inventive concepts have been described, those skilled in the art will readily appreciate that many modifications are possible in the exemplary embodiments without materially departing from the novel teachings and advantages of the inventive concepts. Accordingly, all such modifications are intended to be included within the scope of the inventive concepts as defined in the claims. Therefore, it is to be understood that the foregoing is illustrative of the present inventive concepts and is not to be construed as limited to the specific embodiments disclosed, and that modifications to the disclosed embodiments, as well as other embodiments, are intended to be included within the scope of the appended claims. The inventive concepts are defined by the following claims, with equivalents of the claims to be included therein.

1. A method, comprising:
providing a plurality of semiconductor devices on a semiconductor structure;
providing a top side metallization on a first side of the semiconductor structure, wherein the top side metallization comprises a plurality of bond pads on each of the semiconductor devices; and
providing a back side metallization on a second side of the semiconductor structure opposite the first side of the semiconductor structure;
wherein the back side metallization is not provided on portions of the second side of the semiconductor structure corresponding to dicing streets between the semiconductor devices.

2. The method of claim 1, further comprising singulating the semiconductor structure along the dicing streets.

3. (canceled)

4. The method of claim 1, wherein providing the back side metallization comprises providing a blanket metallization on the second side of the semiconductor structure and selectively removing metal from portions of the second side of the semiconductor structure corresponding to dicing streets.

5. The method of claim 4, wherein selectively removing metal comprises selectively ablating the back side metallization with a laser.

6. The semiconductor device of claim 1, wherein providing the back side metallization comprises selectively depositing metal on the second side of the semiconductor structure other than in portions of the second side of the semiconductor structure corresponding to dicing streets.

7. The method of claim 1, wherein providing the back side metallization comprises forming contact pads on back sides of the semiconductor devices, wherein corners of the contact pads are shaped to reduce stress at corners of the contact pads caused by mounting the semiconductor devices.

8. The method of claim 7, wherein the corners of the contact pads are rounded.

9. The method of claim 8, wherein corners of one of the contact pads are rounded with a radius that is less than about one half of a length of a shortest side of the one of the contact pads.

10-11. (canceled)

12. The method of claim 7, wherein the corners of the contact pads are chamfered.

13. The method of claim 7, wherein the corners of the contact pads have polygonal shapes.

14. (canceled)

15. The method of claim 7, wherein shaping the corners of the contact pads is performed by selectively depositing a plurality of metal layers.

16. The method of claim 1, wherein the back side metallization is not provided on edges of the semiconductor devices.

17. The method of claim 1, further comprising:
selectively removing the back side metallization from portions of the second side of the semiconductor structure other than the portions of the second side of the semiconductor structure corresponding to the dicing streets between the semiconductor devices.

18. The method of claim 1, wherein providing the back side metallization comprises depositing a plurality of metal layers on the second side of the semiconductor structure.

19. The method of claim 1, wherein providing the back side metallization comprises performing patterned deposition of metal on the second side of the semiconductor structure.

20. The method of claim 1, wherein providing the back side metallization comprises performing depositing metal on the second side of the semiconductor structure and selectively etching portions of the deposited metal.

21. A method, comprising:
providing a plurality of semiconductor devices on a semiconductor structure;
providing a top side metallization on a first side of the semiconductor structure, wherein the top side metallization comprises a plurality of bond pads on each of the semiconductor devices; and
providing a back side metallization on a second side of the semiconductor structure opposite the first side of the semiconductor structure, wherein portions of the second side of the semiconductor structure are free of the back side metallization.

22-27. (canceled)

28. The method of claim 21, further comprising forming a protective overlay on the top side metallization, wherein the protective overlay comprises an opening aligned with at least one of the bond pads, wherein the opening has rounded corners.

29. (canceled)

30. A semiconductor device, comprising:
a semiconductor structure;
a top side metallization on a first side of the semiconductor structure, wherein the top side metallization comprises a plurality of bond pads; and
a back side metallization on a second side of the semiconductor structure opposite the first side of the semiconductor structure;
wherein edges of the back side metallization are inset from edges of the semiconductor structure.

31-39. (canceled)

40. A method, comprising:
providing a plurality of semiconductor devices on a semiconductor structure;
providing a top side metallization on a first side of the semiconductor structure, wherein the top side metallization comprises a plurality of bond pads on each of the semiconductor devices; and
forming a protective overlay on the top side metallization, wherein the protective overlay comprises an opening aligned with at least one of the bond pads, wherein the opening has rounded corners.

41-44. (canceled)
